(19) United States
(12) Patent Application Publication
(10) Pub. No.: US 2015/0106045 A1
(43) Pub. Date: Apr. 16, 2015

(54) MEASUREMENT METHOD, MEASUREMENT DEVICE, AND MEASUREMENT PROGRAM

(71) Applicant: Sony Corporation, Tokyo (JP)

(72) Inventors: Jusuke Shimura, Kanagawa (JP); Masahiro Morooka, Kanagawa (JP)

(73) Assignee: Sony Corporation, Tokyo (JP)

(21) Appl. No.: 14/381,260

(22) PCT Filed: Feb. 22, 2013
(86) PCT No.: PCT/JP2013/055608

§ 371 Date: Aug. 27, 2014

(30) Foreign Application Priority Data
Mar. 8, 2012 (JP) 2012-052187

(51) Int. Cl. G01R 19/25; G01R 22/10

(52) U.S. Cl. CPC G01R 19/2506; G01R 22/10
USPC 702/64

(57) ABSTRACT

There is provided a measurement method for an electrical characteristic, the measurement method including applying a voltage to an element, and determining stability of a current value at the applied voltage.

### TECHNICAL FIELD

The present technology relates to a measurement method, a measurement device, and a measurement program. Specifically, the technology relates to a measurement method for measuring an electrical characteristic of an element.

### BACKGROUND ART

An electrical response of a dye-sensitized solar cell is much later than that of solar cells of other types, including silicon-type solar cells. When, for example, a current value is measured by applying a voltage to both poles of a solar cell, a current change is extensive immediately after the voltage is applied, and thus it is necessary to wait a substantial time to obtain a correct and stable current value. A proper waiting time differs depending on a structure, a constituent member, a degree of deterioration, or the like of a dye-sensitized solar cell to be measured. Thus, in order to decide a waiting time that is neither too long nor too short, preparation such as repeating advance measurements over and over, measuring a time constant in advance, or the like is generally indispensible.

Patent Literature 1 discloses a technology for accurately and quickly measuring an output characteristic of a photoelectric conversion element that uses an organic material with a time constant measured in advance.

### CITATION LIST

### Patent Literature

Patent Literature 1: JP 2005-317811A

### SUMMARY OF INVENTION

### Technical Problem

It is, however, hard to say that such advance preparation is possible at all times. A dye-sensitized solar cell that has been built as a prototype in the course of research, for example, often lacks sufficient durability and performance changes gradually each time advance measurement is repeated, and thus it is quite difficult to decide a correct measurement condition or to obtain an accurate measurement result. Particularly, in the field of research and development, demand for a technique of performing such measurement with a waiting time that is neither too long nor too short without performing advance measurement is very high.

Thus, an objective of the present technology is to provide a measurement method, measurement device, and measurement program that enable measurement of an electrical characteristic with a waiting time that is neither too long nor too short without performing advance measurement.

### Solution to Problem

In order to solve the above described problems, according to a first technology, there is provided a measurement method for an electrical characteristic, the measurement method including applying a voltage to an element, and determining stability of a current value at the applied voltage.

According to a second technology, there is provided a measurement program for an electrical characteristic causing a computer device to execute a measurement method including applying a voltage to an element, and determining stability of a current value at the applied voltage.

According to a third technology, there is provided a measurement device for an electrical characteristic including a control unit configured to control a power source unit such that a voltage is applied to an element and stability of a current value at the applied voltage is determined.

### Advantageous Effects of Invention

As described above, according to the present technology, an electrical characteristic can be measured with a waiting time that is neither too long nor too short without performing advance measurement.

### BRIEF DESCRIPTION OF DRAWINGS

FIG. 1 is a diagram showing a plot of NPCCR (nΔt) vs. P (nΔt) and a plot of NPCCR (nΔt) vs. Q (nΔt).

FIG. 2 is a diagram showing an approximation function Q′(t) simulating Q(t) and its behavior.

FIG. 3 is a schematic diagram showing a configuration example of a measurement device according to an embodiment of the present technology.

FIG. 4 is a block diagram showing a configuration example of a control device.

FIG. 5 is a diagram showing a time dependency of an applied voltage.

FIG. 6 is a flowchart for describing a measurement method of an I-V curve.

FIG. 7 is a flowchart for describing a process of measurement preparation (Step S1) shown in FIG. 6.

FIG. 8 is a flowchart for describing a process of measuring a provisional short-circuit current value Isc and open voltage value Voc (Step S2) shown in FIG. 6.

FIG. 9 is a flowchart for describing a process of I-V curve measurement preparation (Step S3) shown in FIG. 6.

FIG. 10 is a flowchart for describing a process of I-V curve measurement (forwarding course: Step S4) shown in FIG. 6.

FIG. 11 is a flowchart for describing a process of I-V curve measurement (returning course: Step S5) shown in FIG. 6.

FIG. 12 is a flowchart for describing a process of measurement data analysis (Step S7) shown in FIG. 6.

FIG. 13 is a flowchart for describing a process termination (Step S8) shown in FIG. 6.

FIG. 14 is a flowchart for describing a first determination method.

FIG. 15 is a flowchart for describing a second determination method.

FIG. 16 is a flowchart for describing the second determination method.

FIG. 17 is a flowchart for describing a third determination method.

FIG. 18 is a flowchart for describing the third determination method.

FIG. 19 is a flowchart for describing a fourth determination method.

FIG. 20 is a flowchart for describing the fourth determination method.

FIG. 21 is a diagram showing the I-V characteristics obtained through measurement methods of Examples 1-1 and 1-2 and Comparative examples 1-1 and 1-2.

FIG. 22 is a diagram showing the I-V characteristics obtained through measurement methods of Examples 2-1 and 2-2 and Comparative examples 2-1 and 2-2.

FIG. 23 is a diagram showing the I-V characteristics obtained through measurement methods of Examples 3-1 and 3-2.

FIG. 24 is a diagram showing times taken to measure each current value (to measure each plot) shown in FIG. 23.

FIG. 25 is a diagram showing the I-V characteristics obtained through measurement methods of Examples 4-1 and 4-2.

FIG. 26 is a diagram showing times taken to measure each current value (to measure each plot) shown in FIG. 25.

FIG. 27A is a diagram showing the I-V characteristics obtained through measurement methods of Comparative examples 3-1 to 3-3.

FIG. 27B is a diagram showing the I-V characteristics obtained through measurement methods of Examples 5-1 to 5-3.

### DESCRIPTION OF EMBODIMENTS

Embodiments of the present technology will be described in the following order.

(1) Overview of Examination

(2) Theory of the Present Technology

(3) Specific Application of the Present Technology

(4) Configuration of a Measurement Device

(5) Measurement Method of an I-V Curve

(6) Determination Method of a Current Value and a Voltage Value of a Stable State

(7) Modified example

### (1) Overview of Examination

The present inventors have deliberatively examined the above-described problem in order to solve it. According to knowledge of the present inventors, as one method for omitting advance measurement, there is a method in which a current value iₘ(t) is repeatedly measured at a fixed time interval Δt immediately after a voltage is applied, the absolute value of the difference of two consecutive measurement values is calculated, it is checked whether the value is below a certain threshold value, and thereby it is determined whether the value converges. If the method is expressed with a formula, formula (1) below is a termination determination condition for waiting for stability.

|iₘ(t+Δt)−iₘ(t)|<Threshold (1)

Such thinking is simple and understandable, but also has many demerits. One is that it is necessary for a user to set the threshold value. If the set value is excessively low, the user has to wait longer than necessary due to influence of a measurement error, and if the set value is excessively high, it is difficult to fully exhibit measurement accuracy of a measuring instrument. Furthermore, even if a correct threshold value is set, individual current measurement values iₘ(t) generally include an error ε as indicated in the following formula:

iₘ(t)=iₜ(t)+ε (2)

and there is a possibility of measurement accidentally terminating before the measurement reaches a stable state due to influence of the error. Note that iₜ(t) in formula (2) is a true value of a current. If the error ε is a random error attributable to the measuring instrument and set to comply with the normal distribution of a standard deviation a, the desirable termination determination condition for waiting for stability can be written, for example, as the following formula (3).

|iₜ(∞)−iₜ(t)|<σ (3)

That is to say, formula (3) represents the condition that the measurement is terminated when the difference between the true value of the present current and the convergence value is smaller than the level of noise (standard deviation) that the measurement device has.

In the present specification, a method that enables measurement under the condition of (3) with no necessity for a user to directly set a waiting time or a threshold value for termination determination, in other words, without using an experience parameter at all, will be described.

### (2) Theory of the Present Technology

The method that will be described in the present specification focuses on current measurement values iₘ(t) and iₘ(t+Δt) at times t and t+Δt, current true values iₜ(t) and iₜ(t+Δt) that do not include an error, and change amounts thereof Δiₘ(t) and Δiₜ(t).

Change amount of current measurement values: Δiₘ(t)≡iₘ(t+Δt)−iₘ(t) (4)

Change amount of current true values: Δiₜ(t)≡iₜ(t+Δt)−iₜ(t) (5)

While stability of current values is awaited, the true value iₜ(t) monotonically increases or monotonically decreases, and the sign of a change amount of the current true value Δiₜ(nΔt) is the same at all times regardless of a measurement point n. However, since the current measurement value iₘ(t) includes the error ε of the standard deviation σ, the sign of the change amount iₘ(nΔt) is not the same. In a situation in which Δiₜ(nΔt) is far greater than σ, the sign of Δiₘ(nΔt) is substantially the same regardless of the measurement point n, but on the other hand, in a situation in which |Δiₜ(nΔt)| is far smaller than σ, the sign of Δiₘ(nΔt) changes nearly randomly in each measurement.

When |Δiₜ(nΔt)|>>σ: The sign of Δiₘ(nΔt) is substantially constant. (6)

When |Δiₜ(nΔt)|<<σ: The sign of Δiₘ(nΔt) randomly changes. (7)

Herein, an index of a Noise Per Current-Change Ratio (NPCCR) that indicates a ratio of |Δiₜ(t)| and σ will be defined [see formula (8)]. The index indicates a change amount of a current true value with respect to a variation (standard deviation) of a measurement value. When NPCCR (nΔt) is used, (6) and (7) can be rewritten as (9) and (10) respectively.

$$\begin{matrix}NPCCR ( t ) ≡ \vert \frac{σ}{Δ {i}_{t} ( t )} \vert & ( 8 ) \\ When NPCCR ( n Δ t ) ≪ 1 \text{:} \\ The sign of Δ {i}_{m} ( n Δ t ) is substantially constant . & ( 9 ) \\ When NPCCR ( n Δ t ) ≫ 1 \text{:} \\ The sign of Δ {i}_{m} ( n Δ t ) randomly changes . & ( 10 )\end{matrix}$$

Next, the quantitative relationship between NPCCR(nΔt) and a probability Q(nΔt) that the sign of iₘ(nΔt) is reversed will be considered. In the case of the situation (9) in which NPCCR(nΔt) is far smaller than 1, the sign of iₘ(nΔt) is substantially the same, in other words, the probability Q(nΔt) of reversal of a sign is substantially zero. On the other hand, in the situation (10) in which NPCCR(nΔt) is far greater than 1, the sign of iₘ(nΔt) is randomly changed each time of measurement, and the probability Q(nΔt) of reversal of a sign is substantially 0.5. Although the behavior of Q(nΔt) under such extreme conditions is easy to understand, a behavior of Q(nΔt) under an intermediate situation is somewhat complicated. When it is quantitatively considered, first, a probability P₊(nΔt) that iₘ(nΔt) becomes a positive value and P₋(nΔt) that iₘ(nΔt) becomes a positive value are elicited. P₊(nΔt) is:

Probability P₊(nΔt): Probability of Δiₘ(nΔt)>0 (11)

Probability P₊(nΔt): Probability of iₘ((n+1)Δt)>iₘ(nΔt)(because of (4)) (12)

and, in other words, is the probability that a current value iₘ(t+Δt) measured at a time t+Δt is greater than a current value iₘ(t) measured at a time t. The probability that iₘ(t+Δt) having a variation of the normal distribution is greater than a certain value can be described using a cumulative normal distribution function. Here, if iₘ(t) itself is considered to include the variation of the normal distribution, the distribution is described with a probability density function, and consequently, P₊(nΔt) and P₋(nΔt) can be described as follows.

P₊(nΔt)=∫_{-∞}^{∞}f(i)·Φ(i)di (13)

P₋(nΔt)=1−P₊(nΔt) (14)

Here, f(i) is the probability density function of the variance of 1 and the mean 1/NPCCR(nΔt), and Φ(i) is the cumulative normal distribution function of the variance 1 and the mean 0. Note that f(i) and Φ(i) can be written as the following formulas respectively. Note that erf(x) is a Gaussian error function.

$$\begin{matrix}f ( i ) = \frac{1}{\sqrt{2 π}} exp [ - \frac{{( i - \frac{1}{NPCCR ( n Δ t )} )}^{2}}{2} ] & ( 15 ) \\ Φ ( i ) = \frac{1}{2} [ 1 + erf ( \frac{i}{\sqrt{2}} ) ] & ( 16 )\end{matrix}$$

In addition, the probability Q(nΔt) of the reversal of the sign is immediately obtained from (13) and (14), i.e., as follows.

Q(nΔt)=P₊(nΔt)·P₋((n+1)Δt)+P₋(nΔt)·P₊((n+1)Δt) (17)

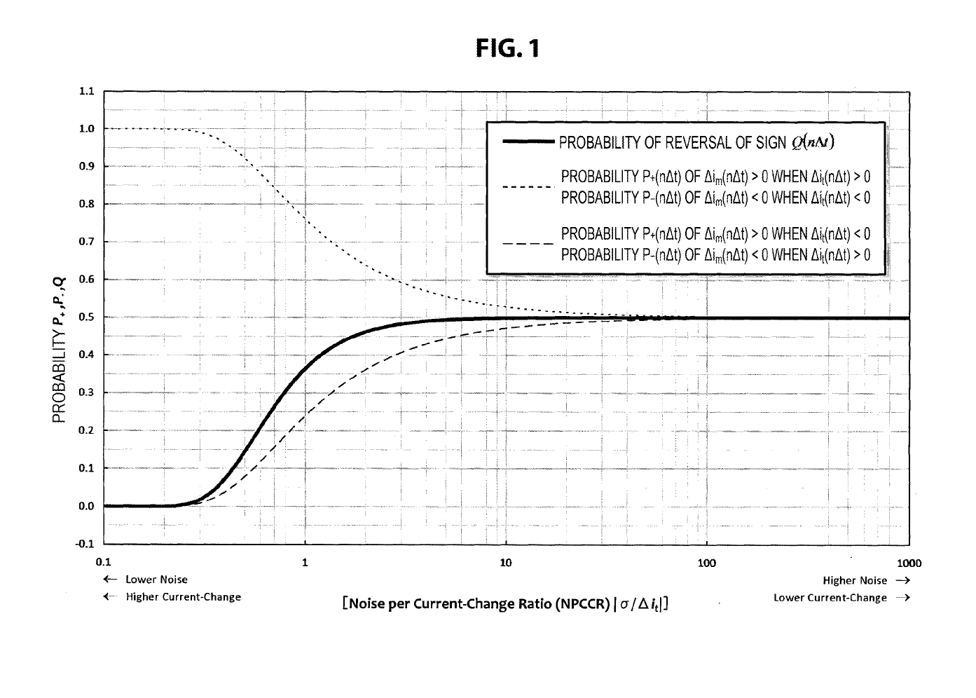

FIG. 1 shows the plot of NPCCR (nΔt) vs. P(nΔt) and the plot of NPCCR(nΔt) vs. Q(nΔt) that are numerically calculated under the condition of iₜ((n+1)Δt)=iₜ(nΔt).

Next, the termination determination of waiting for stability will be considered. When a transient response of the current true value iₜ(t) is set to be exponential and a time constant thereof is set to be τ, the current true value is expressed as the following formula. Note that i_{t,conv} is a convergence value of the current true value.

$${i}_{t} ( t ) = a exp ( - \frac{t}{τ} ) + {i}_{t , conv} \qquad ( 18 )$$

When the slopes of the function at t₁ and t₂ are to be obtained, they are:

$$\begin{matrix}\frac{d}{d t} {i}_{t} ( {t}_{1} ) = - \frac{a}{τ} exp ( - \frac{{t}_{1}}{τ} ) \approx \frac{Δ {i}_{t} ( {t}_{1} )}{Δ t} & ( 19 ) \\ \frac{d}{d t} {i}_{t} ( {t}_{2} ) = - \frac{a}{τ} exp ( - \frac{{t}_{2}}{τ} ) \approx \frac{Δ {i}_{t} ( {t}_{2} )}{Δ t} & ( 20 )\end{matrix}$$

and when a is eliminated simultaneously with (19) and (20),

$$\frac{{t}_{2} - {t}_{1}}{τ} = \frac{ln Δ {i}_{t} ( {t}_{1} )}{ln Δ {i}_{t} ( {t}_{2} )} = \frac{ln NPCCR ( {t}_{2} )}{ln NPCCR ( {t}_{1} )} \qquad ( 21 )$$

is obtained. When the above is further organized with τ,

$$τ = \frac{{t}_{2} - {t}_{1}}{ln NPCCR ( {t}_{2} ) - ln NPCCR ( {t}_{1} ) } \qquad ( 22 )$$

is obtained. If the probability Q(t) of the reversal of the sign is an actually measurable value and Q(t₁) and Q(t₂) at t₁ and t₂ are measured, τ and Q(t) can be obtained respectively using FIG. 1. In addition, when the obtained values are applied to (22), the time constant τ of the current true value iₘ(t) can be computed.

Next, a specific termination determination condition is considered. If the determination condition is assumed to be defined as (3), i.e.,

|iₜ(∞)−iₜ(t)|<σ (23)

modification of the formula of |iₜ(∞)−iₜ(t)| on the left side is made as follows:

$$\begin{matrix}\vert {i}_{t} ( ∞ ) - {i}_{t} ( t ) \vert = \vert {lim}_{t \to ∞} {i}_{t} ( t ) - {i}_{t} ( t ) \vert \\ = \vert {i}_{t , conv} - a exp ( - \frac{t}{τ} ) - {i}_{t , conv} \vert \\ = \vert - a exp ( - \frac{t}{τ} ) \vert\end{matrix} \qquad ( 24 )$$

and becomes as follows simultaneously with (19).

$$\vert {i}_{t} ( ∞ ) - {i}_{t} ( t ) \vert = \frac{τ}{Δ t} \vert Δ {i}_{t} ( t ) \vert \qquad ( 25 )$$

Then, based on (8), (23), and (25), the termination determination condition is as follows.

$$\frac{τ}{Δ t} < NPCCR ( t ) \qquad ( 26 )$$

A specific picture of measurement in which the termination determination is performed using (26) is as follows. The measurement of the probability Q(t) of the reversal of the sign continues while the current is measured at a fixed time interval Δt, Q(t₁) and Q(t₂) are measured at times t₁ and t₂ during the measurement, and the time constant τ is thereby obtained using (22). The measurement of Q(t) continues without change, then the measurement is stopped immediately when the condition of (26) is satisfied, and the finally measured current value iₘ(t) is taken. By adopting this method, the measurement can be performed:
without performing an advance review at all;
for a measurement time that is neither too long nor too short; and
at a level of a measurement error that the measurement device has.

### (3) Specific Application of the Present Technology

Next, points to be aware of when the present method is applied to actual measurement and a specific algorithm when it is executed using a computer will be described.

### (Deciding a Measurement Interval)

First of all, a way of deciding a measurement interval Δt will be described. It is desirable to set multiplication of a power line cycle when a measuring instrument is driven by AC power for the purpose of reducing noise caused by a power line. In other words, Δt is an integral multiple of 20 ms (20 ms, 40 ms, 60 ms, . . . ) in a region with AC power of 50 Hz, and an integral multiple of 16.67 ms (16.67 ms, 33.33 ms, 50 ms, . . . ) in a region of 60 Hz. Note that, when a measurement system that can be used in both regions is considered, it may be 100 ms or an integral multiple thereof (100 ms, 200 ms, 300 ms, . . . ) that is the least common multiple. When the measuring instrument is driven by DC power, the measurement interval Δt can be freely set. In most cases, however, if the measurement interval Δt is set to be long, an accumulated time per piece of data tends to increase, and accordingly the variation σ reduces. In such a case, σ is a more important parameter than Δt, and thus if σ that enables a desired measurement accuracy to be obtained is decided beforehand, the measurement interval Δt is naturally decided.

(Deciding t₁ and t₂)

Next, a way of deciding the measurement points t₁ and t₂ which are used for obtaining the time constant τ will be described, and in order to obtain the correct τ, it is better to select the two points within the range in which the slope of Q(t) in FIG. 1 is high, in other words, in the range in which Q(t) falls approximately between 0.05 and 0.45. Since a timing at which t₁ and t₂ fall into this range differs from measurement samples, t₁ and t₂ are not decided in advance, and it is better to decide Q(t₁) and Q(t₂) in advance and then obtain t₁ and t₂ of the time in such a way that:
an elapsed time in which the probability Q(t) that the reversal of the sign satisfies Q(t)=0.05 for the first time is set to t₁; and
an elapsed time in which the probability Q(t) that the reversal of the sign satisfies Q(t)=0.25 for the first time is set to t₂,
   while Q(t) during the measurement is continuously monitored. If Q(t₁) and Q(t₂) are respectively decided to be 0.05 and 0.20, NPCCR(nΔt) thereof is respectively 0.3631 and 0.5888 based on FIG. 1. If these are applied to (22), the following formula is obtained:

τ=2.068(t₂−t₁) (27)

and only by deciding Q(t₁) and Q(t₂) in advance, is the time constant τ easily obtained.

### (Specific Method of the Termination Determination)

The termination determination condition for waiting for stability is obtained from (26). τ/Δt of the left side of (26) is immediately decided after the time constant τ is decided, but on the other hand, it is not easy to obtain NPCCR(nΔt) of the right side. It should be obtained through numerical calculation using (13) to (17) based on Q(t) changing moment to moment in order to perform correct calculation, but such calculation is by no means easy. In order to avoid the calculation, preparing the relationship of NPCCR(nΔt) and Q(t) as a conversion table is a practical method. If such a conversion table is prepared, the termination determination condition for waiting for stability is alleviated to be the condition for “termination when the difference is smaller than the level of noise (standard deviation) that the measurement device has” as in the condition for the determination on termination (3), “termination when the difference is smaller than two times the standard deviation,” or “termination when the difference is smaller than three times the standard deviation,” and accordingly, the balance between the measurement time and accuracy is also easily adjusted. A specific algorithm of the termination determination using the conversion table is, for example, as follows.

### <<Algorithm of the Termination Determination>>

### <Step 1>

While waiting for stability, a current value iₘ(t) is measured at an interval Δt, and at the same time, Q(t) is also calculated.

### <Step 2>

An elapsed time when Q(t)=0.05 is satisfied for the first time is set to t₁.

An elapsed time when Q(t)=0.20 is satisfied for the first time is set to t₂.

### <Step 3>

The time constant τ is obtained using (27), and τ/Δt is further calculated.

### <Step 4>

If τ/Δt=2.068, the waiting is terminated at the time at which the probability Q(t) of the reversal of the sign>0.464 is satisfied.

If τ/Δt=2.068×2, the waiting is terminated at the time at which the probability Q(t) of the reversal of the sign>0.491 is satisfied.

If τ/Δt=2.068×3, the waiting is terminated at the time at which the probability Q(t) of the reversal of the sign>0.496 is satisfied.

If τ/Δt=2.068×4, the waiting is terminated at the time at which the probability Q(t) of the reversal of the sign>0.498 is satisfied.

If τ/Δt≧2.068×5, the waiting is terminated at the time at which the probability Q(t) of the reversal of the sign>0.499 is satisfied.

With regard to values of t₁ and t₂, the result of t₂−t₁ is necessarily an integral multiple of Δt as long as the measurement interval is Δt. In other words, the time constant τ obtained from (27) has discrete values as follows:

$$\begin{matrix}τ = 2.068 \cdot Δ t \\ τ = 2.068 \cdot 2 Δ t \\ τ = 2.068 \cdot 3 Δ t \\ ⋮ \\ τ = 2.068 \cdot n Δ t\end{matrix}$$

and τ/Δt becomes also discrete. This is the reason for the classification of the cases under the discrete conditions in <<Algorithm of the termination determination>> described above.
(Method for Obtaining the Probability Q(t) of Reversal with High Accuracy)

It is very important to obtain Q(t) with high accuracy after the correct termination determination is performed using the present algorithm. The phenomenon of the reversal of the sign, however, is a phenomenon of, so to speak, turning into 0 or 1, and computing accurate Q(t) that is an analog value from the phenomenon is not easy. Herein, two specific methods thereof will be introduced.

A first method thereof uses a moving average. If Q(t) is computed with resolving power of 0.001, measurement results from the present one to the one 1,000 measurements before are focused, the number of sign reversals in the 1,000 measurements is counted, and then the counting number may be divided by 1,000. This method is very easy in programming, but on the other hand, it should be noted that there is a demerit that such programming causes a serious delay. It is assumed that Q(t) satisfying the condition that Q(t)>0.464 is being awaited. In addition, it is assumed that the true value of Q(t) has satisfied the condition. Whether or not it is satisfied, however, can be ascertained using the moving average method after 1,000 measurements are further performed. The time taken for 1,000 measurements is 16.67 seconds even if the measurement interval Δt is set to 16.67 ms which is a low value. That much time is actually wasted. If it is intended to reduce a delay, the resolving power is sacrificed, and on the other hand, if it is intended to improve the resolving power, the delay increases. This is the demerit of the moving average method.

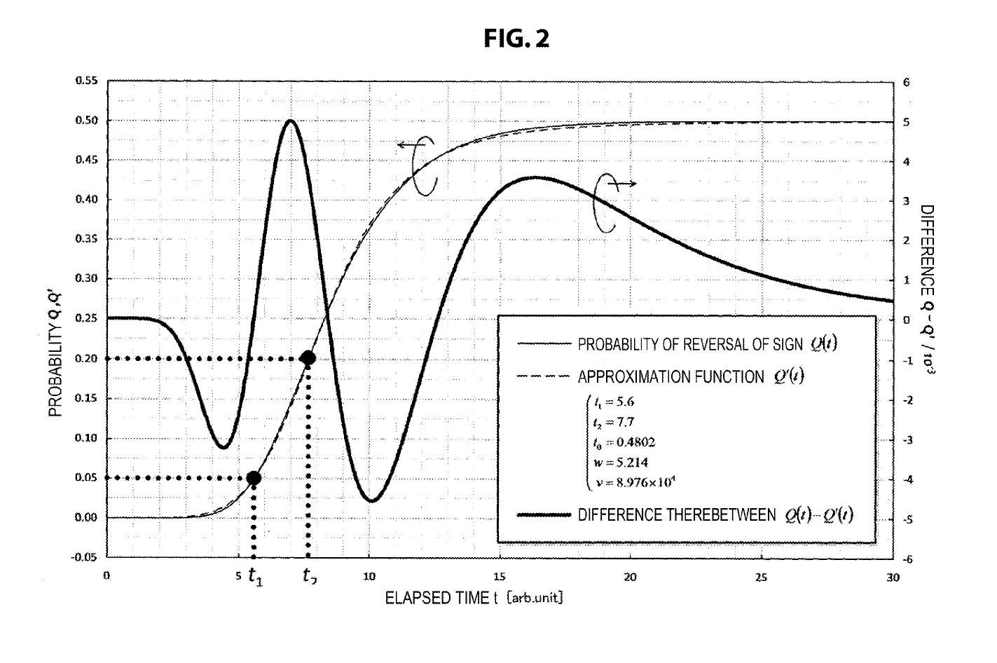

The second method thereof uses an approximation function. Although this is not a physically correct method, it is a method with extremely high practicality. First, the behavior of Q(t) of FIG. 1 will be reviewed again. Immediately after waiting for stability of a current is started, the change amount Δiₘ(t) is great, and for this reason, reversal of the sign does not occur, and the probability of reversal Q(t) is substantially zero. In other words, the probability can be said to be in a left region of FIG. 1. Then, as time elapses, the sign of iₘ(t) gradually changes, the value of Q(t) also increases little by little, and then finally, gradually approaches 0.5 asymptotically. This means that the state of FIG. 1 moves from the left region to the right region. Here, adding a time axis to FIG. 1 will be considered. Since the case in which a transient response of the current true value iₜ(t) is described as the exponential function as in (18) is dealt with herein, Δiₜ(t) decreases exponentially according to the elapse of time, and NPCCR(t) increases exponentially [because of (8)]. Thus, when the time axis is added to FIG. 1, the time axis with linear scales may overlap NPCCR(t) with logarithmic scales without change. A graph in which the horizontal axis of FIG. 1 is actually replaced by elapsed time t is shown in FIG. 2.

Here, the concept of the approximation function is adopted. Time dependency of Q(t) can be numerically calculated using (13) to (18), but is difficult to solve analytically. On the other hand, a function Q′(t) that behaves extremely similarly to Q(t) can be written as follows.

$${Q}^{′} ( t ) = \frac{{( t - {t}_{0} )}^{w}}{v + 2 {( t - {t}_{0} )}^{w}} \qquad ( 28 )$$

Note that the coefficients t₀, w, and v in (28) are obtained respectively using the following formulas based on t₁ and t₂ that satisfy Q(t₁)=0.05 and Q(t₂)=0.20.

$$\begin{matrix}{t}_{0} = 3.438 {t}_{1} - 2.438 {t}_{2} & ( 29 ) \\ w = \frac{1.792}{ln ( {t}_{2} - {t}_{0} ) - ln ( {t}_{1} - {t}_{0} )} & ( 30 ) \\ v = 18 {( {t}_{1} - {t}_{0} )}^{w} & ( 31 )\end{matrix}$$

The course of elicitation of (28) to (31) will be omitted since it has no physical implication, but as shown in FIG. 2, it is found that the approximation function Q′(t) obtained through the formulas shows good coincidence with Q(t). Once the approximation function Q′(t) is decided as above, it is no longer necessary to observe the current reversal phenomenon. When there is even the elapsed time t, Q′(t) can be computed, and the result can be used in the termination determination. Note that, in order to obtain the accurate coefficients t₀, w, and V of the approximation function Q′(t), the correct values of t₁ and t₂ should be obtained, and they can be easily obtained in the moving average method. This is because both t₁ and t₂ can be obtained in a region with a great slope of Q(t), and Q(t) can be obtained with resolving power of about 0.025 (in other words, about 40 in terms of a number n of the moving average).

Note that, in the number n of the moving average, n does not have the feature that a correct value is obtained as the value increases, and an optimum value can be elicited based on the cumulative Poisson distribution. Specifically, when Q(t1)=0.05 is obtained, it is better to set n=40. If two or more reversals of the sign have occurred in 40 times of execution in the past, it can be said that Q(t1) 0.05 was satisfied with a probability of 59.4%. If n=50, 60, and 70, the probabilities are 45.6%, 57.7%, and 46.3% respectively, and thus it is difficult to make a determination as correct as when n=40 in all of the cases. In addition, when Q(t2)=0.20 is obtained, it is better to set n=10. If two or more reversals of the sign have occurred in 10 times of execution in the past, it can be said that Q(t2) 0.20 was satisfied with a probability of 59.4%. If n=20, 30, and 40, the probabilities are 56.7%, 55.4%, and 54.7% respectively, and thus it is difficult to make a determination as correct as when n=10 in all of the cases.

(Additional Measurement after the Determination on Termination)

A behavior after a condition for termination will be briefly described. When the condition for termination has been satisfied but the current value at the time is iₘ(nΔt) in an n^{th} measurement, the value may be accepted as it is, but when k more measurements of currents are additionally performed as shown in (32) and the average thereof is taken, more accurate values can be obtained. It may be decided whether the additional measurement should be performed, and if so, how many measurements will be performed based on the balance with a total measurement time. Note that the average value of iₘ shown in (32) is a k-point averaged current measurement value.

$$\overline{{i}_{m}} = \frac{1}{k} {\sum }_{j = n}^{n + k - 1} {i}_{m} ( j Δ t ) \qquad ( 32 )$$

### (Conclusion)

Finally, an algorithm that includes all factors described above will be shown below. By combining the algorithm with a current measurement program, measurement is possible:
without performing an advance review at all;
for a measurement time that is neither too long nor too short; and
at a level of a measurement error that the measurement device has.

### <<Algorithm of the Determination on Termination>>

### <Step 1>

While waiting for stability, a current value iₘ(t) is measured at a time interval Δt.

Focusing on the results of the latest n measurements, Q(t) is calculated using the moving average method.

### <Step 2>

An elapsed time when Q(t)=0.05 is satisfied for the first time is set to t₁.

An elapsed time when Q(t)=0.20 is satisfied for the first time is set to t₂.

### <Step 3>

When both t₁ and t₂ are obtained, the calculation of Q(t) using the moving average method is stopped.

Instead, t₀, w, and v are obtained using (29) to (31), and thereafter, Q′(t) is calculated for each Δt using (28).

### <Step 4>

The time constant τ is obtained using (27), and τ/Δt is further calculated.

### <Step 5>

If τ/Δt=2.068, the waiting is performed until the probability Q′(t) that the reversal of the sign>0.464 is satisfied.

If τ/Δt=2.068×2, the waiting is performed until the probability Q′(t) that the reversal of the sign>0.491 is satisfied.

If τ/Δt=2.068×3, the waiting is performed until the probability Q′(t) that the reversal of the sign>0.496 is satisfied.

If τ/Δt=2.068×4, the waiting is performed until the probability Q′(t) that the reversal of the sign>0.498 is satisfied.

If τ/Δt=2.068×5, the waiting is performed until the probability Q′(t) that the reversal of the sign>0.499 is satisfied.

### <Step 6>

k more measurement of currents are additionally performed, and the average value thereof is accepted.

### (4) Configuration of a Measurement Device

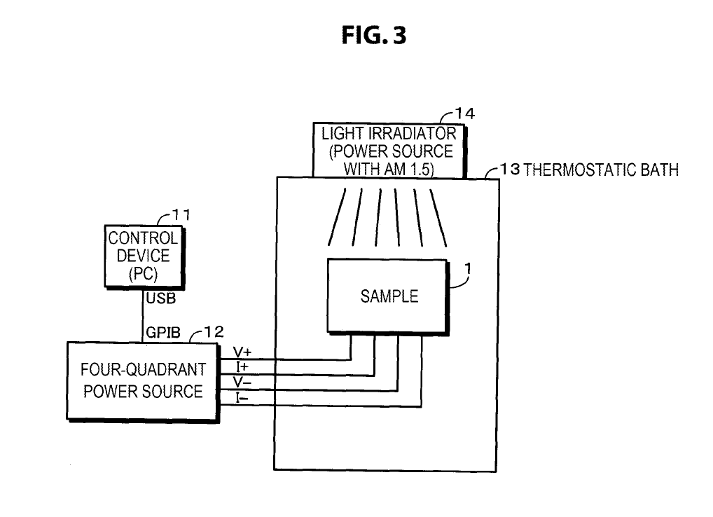

FIG. 3 is a schematic diagram showing a configuration example of a measurement device according to an embodiment of the present technology. The measurement device is a measurement device that measures an electrical characteristic such as a current-voltage characteristic, and includes a control device 11, a four-quadrant power source 12, a thermostatic bath 13, and a light irradiator 14 as shown in FIG. 3. A sample 1 to be measured is contained in a high-temperature bath, and light from the light irradiator 14 is radiated to the contained sample 1. The control device 11 and the four-quadrant power source 12 are electrically connected, and the four-quadrant power source 12 and the sample 1 are electrically connected.

### (Sample)

The sample 1 is, for example, an element. The element is, for example, a photoelectric conversion element or a battery. The photoelectric conversion element or the battery is, for example, a battery in which ions have charge of part of movement of charges, or a photoelectric conversion element or a battery accompanied by an oxidation reaction and a reduction reaction of a chemical species therein. As the photoelectric conversion element, a dye-sensitizing photoelectric conversion element, an amorphous photoelectric conversion element, a compound semiconductor photoelectric conversion element, a thin-film polycrystalline photoelectric conversion element, and the like are exemplified, but the photoelectric conversion element is not limited thereto. As a battery, a fuel cell, a primary battery, or a secondary battery are exemplified, but the battery is not limited thereto. As a fuel cell, for example, a solid polymer battery, a phosphoric acid fuel cell, a solid oxide fuel cell, a molten carbonate fuel cell, an enzyme battery, and the like are exemplified, but the fuel cell is not limited thereto. As a primary battery, for example, a manganese battery, an alkaline manganese battery, a nickel battery, a lithium battery, a silver oxide battery, a zinc-air battery, and the like are exemplified, but the primary battery is not limited thereto. As a secondary battery, for example, a lithium-ion secondary battery, a nickel-hydrogen battery, a nickel-cadmium battery, a lead storage battery, and the like are exemplified, but the secondary battery is not limited thereto. The measurement device according to the embodiment is preferred to be used in measurement of an electrical characteristic of an element and a battery showing a late electrical response among the above elements and batteries, and particularly is desirable to be used in an element and a battery such as a dye-sensitizing photoelectric conversion element showing a late electrical response due to ions in charge of part of movement of charges.

### (Light Irradiator)

The light irradiator 14 irradiates the sample 1 contained in the thermostatic bath 13 with pseudo-sunlight (for example, AM 1.5 and 100 mW/cm²). As a light source of the light irradiator 14, for example, a xenon lamp, a metal halide lamp, an LED (Light Emitting Diode) or the like can be used, but the light source is not limited thereto. Note that, when the measurement device is used as a device dedicated to an element other than the photoelectric conversion elements such as a lithium-ion secondary battery, the light irradiator 14 can be omitted from the configuration of the measurement device.

### (Control Device)

The control device 11 is a device for executing the measurement methods described above, and an electrical characteristic of the sample 1 is measured by the control device 11. The control device 11 is, for example, a general personal computer or a device having a configuration equivalent to a computer device. Note that the control device 11 has a configuration that is not limited thereto, and may be a dedicated control device specialized in measurement of an electrical characteristic of a photoelectric conversion element, a battery, or the like.

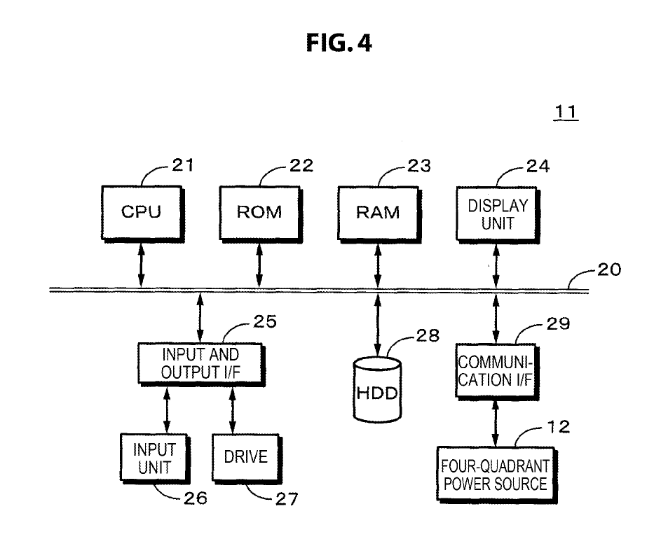

FIG. 4 is a block diagram showing a configuration example of the control device. In the control device 11, a CPU (Central Processing Unit) 21, a ROM (Read Only Memory) 22, and a RAM (Random Access Memory) 23 are connected to a bus 20. The ROM 22 stores, for example, an initial program for activating the control device 11 in advance. The RAM 23 is used as a work memory of the CPU 21.

Furthermore, a display unit 24, an input and output interface (input and output I/F) 25, a hard disk drive (hereinafter appropriately referred to as an “HDD”) 28, and a communication interface (communication I/F) 29 are connected to the bus 20. The display unit 24 is used by being built in the control device 11 or connected to the control device 11, and performs display according to display control signals generated by the CPU 21. An input unit 26 such as a keyboard or a manipulation panel in which a predetermined manipulator is disposed for accepting inputs from a user is connected to the input and output I/F 25. In addition, a drive device 27 that can reproduce a recording medium including a CD (Compact Disc), a DVD (Digital Versatile Disc), or the like may also be connected to the input and output I/F 25.

An HDD 28 stores, for example, a measurement program and a conversion table. Here, the measurement program is a control program for controlling operations of the control device 11 and effectuating each method described above. The control program may be set to be stored in a storage unit such as the HDD 28 in such a way that the measurement program is received via a network such as the Internet. In addition, the measurement program is read from a recording medium loaded on the drive device 27 and saved in a storage unit such as the HDD 28. In this case, the measurement program is stored in the recording medium in advance, and the measurement program is distributed to users as in the recording medium. When the control device 11 is to be activated, for example, the CPU 21 reads the measurement program recorded on the hard disk drive 28 according to the initial program read from the ROM 22, and the program is developed in the RAM 23 to control operations of the control device 11.

The communication I/F 29 is, for example, connected to the four-quadrant power source 12. The CPU 21 controls the four-quadrant power source 12 via the communication I/F 29. The communication I/F 29 is, for example, a “USB (Universal Serial Bus), an RS-232C (Recommended Standard 232 version C), a GPIB (General Purpose Interface Bus), a LAN (Local Area Network), or the like.

The control device 11 causes a voltage to be applied to both poles of the sample 1, and then determines stability of a current value of the applied voltage. More specifically, a voltage is applied to a photoelectric conversion element or a battery while being occasionally stopped, and then stability of the current value of each voltage applied with occasional stops is determined. When the current value is determined to be stable, the current value is stored in a storage unit such as the RAM 23.

For example, the control device 11 determines stability of a current value, for example, in the following manner. In other words, the number of reversals of the sign of a change amount of a current is obtained, and whether or not the current is stable is determined based on the number of reversals. Specifically, it is determined whether or not the number of reversals exceeds a prescribed number of reversals. When the number of reversals is determined to have exceeded the prescribed number of reversals, the current value of that time is accepted as a stable current value, and stored in the storage unit. On the other hand, when the number of reversals is determined not to have exceeded a prescribed number of reversals, the number of reversals of the sign of the change amount of the current is obtained again after a prescribed time Δt elapses.

In addition, stability of the current value may be set to be determined as follows. In other words, a probability of reversal of the sign of the change amount of the current is obtained, and then it is determined whether or not the current has stabilized based on the probability of reversal. To be specific, it is determined whether or not the probability of reversal exceeds the prescribed probability of reversal. When the probability of reversal is determined to exceed the prescribed probability of reversal, the current value of that time is accepted as a stabilized current value, and then stored in the storage unit. On the other hand, when the probability of reversal is determined not to exceed the prescribed probability of reversal, the probability of reversal of the sign of the change amount of the current is obtained again after the prescribed time Δt elapses.

Furthermore, stability of the current value may be set to be determined as follows. An approximation function of the probability of the reversal of the sign is obtained, and then it is determined whether or not the value of the approximation function exceeds the prescribed probability of reversal. When the approximation function is determined to exceed the prescribed probability of reversal, the current value of that time is accepted as a stabilized current value, and stored in the storage unit. On the other hand, when the approximation function is determined not to exceed the prescribed probability of reversal, it is determined again whether or not the value of the approximation function exceeds the prescribed probability of reversal after the prescribed time Δt elapses.

The prescribed probability of reversal described above may be obtained as follows. In other words, a termination condition value is obtained from elapsed times T1 and T2 after application of a voltage and a measurement interval Δt of the current value, and then the prescribed probability of reversal is obtained from the termination condition value. When the prescribed probability of reversal is to be obtained from the termination condition value, for example, using a table in which the termination condition value is associated with the prescribed probability of reversal, the prescribed probability of reversal is obtained from the termination condition value.

The conversion table is stored in, for example, a storage unit such as the HDD 28. In the conversion table, “termination condition parameters Z” that are the termination condition value are associated with “probabilities of termination q_final” that are the prescribed probabilities of reversal.” Thus, by referring to the conversion table, a probability of termination q_final that corresponds to a termination condition parameter Z can be extracted. The termination condition parameter Z and the probability of termination q_final will be described later.

In the conversion table, two or more probabilities of termination q_final (for example, q₁_{_{—}}final, q₂_{_{—}}final, . . . , qₙ_{_{—}}final) may be set to be provided as the probabilities of termination q_final. As the conversion table has two or more probabilities of termination q_final, the condition for the determination of termination is alleviated, and balance between a measurement time and accuracy is also easily adjusted.

If a user is allowed to select a desired one from two or more probabilities of termination q_final through a manipulation of a screen before measuring an electrical characteristic when the conversion table has two or more probabilities of termination q_final, one probability of termination q_final can be extracted from the conversion table based on the termination condition parameter Z. In addition, when a user does not specifically set a probability of termination q_final, a probability of termination q_final set as a default may be set to be extracted from the conversion table based on the termination condition parameter Z.

Table 1 shows an example of the conversion table described above. Table 1 exemplifies the conversion table having three probabilities of termination q_final of “termination when the difference is smaller than the standard deviation (a noise level that measurement device has) σ,” “termination when the difference is smaller than two times the standard deviation σ,” or “termination when the difference is smaller than three times the standard deviation σ.”

TABLE 1

| | Probability of termination q_final | | |
|---|---|---|---|
| Termination | Condition for | Condition for | Condition for |
| condition | convergence | convergence | convergence |
| parameter Z | \|iₜ(∞) − iₜ(t)\| < σ | \|iₜ(∞) − iₜ(t)\| < 2σ | \|iₜ(∞) − iₜ(t)\| < 3σ |
| 1 | 0.4641988064 | 0.3720228312 | 0.2584942822 |
| 2 | 0.4907868670 | 0.4641988064 | 0.4231832868 |
| 3 | 0.4958831146 | 0.4837440704 | 0.4641988064 |
| 4 | 0.4976798670 | 0.4907868670 | 0.4795197846 |
| 5 | 0.4985138134 | 0.4940829450 | 0.4867895678 |
| 6 | 0.4989674346 | 0.4958831146 | 0.4907868670 |
| 7 | 0.4992411626 | 0.4969718782 | 0.4932137090 |
| 8 | 0.4994189070 | 0.4976798670 | 0.4947955444 |
| 9 | 0.4995408060 | 0.4981658720 | 0.4958831146 |
| 10 | 0.4996280190 | 0.4985138134 | 0.4966625826 |
| 11 | 0.4996925568 | 0.4987714144 | 0.4972401266 |
| 12 | 0.4997416490 | 0.4989674346 | 0.4976798670 |
| 13 | 0.4997798578 | 0.4991200400 | 0.4980223702 |
| 14 | 0.4998101776 | 0.4992411626 | 0.4982943116 |
| 15 | 0.4998346392 | 0.4993389006 | 0.4985138134 |
| 16 | 0.4998546604 | 0.4994189070 | 0.4986935348 |
| 17 | 0.4998712540 | 0.4994852244 | 0.4988425350 |
| 18 | 0.4998851600 | 0.4995408060 | 0.4989674346 |
| 19 | 0.4998969292 | 0.4995878500 | 0.4990731626 |
| 20 | 0.4999069776 | 0.4996280190 | 0.4991634500 |
| 21 | 0.4999156252 | 0.4996625900 | 0.4992411626 |
| 22 | 0.4999231206 | 0.4996925568 | 0.4993085312 |
| 23 | 0.4999296600 | 0.4997187022 | 0.4993673128 |
| 24 | 0.4999353992 | 0.4997416490 | 0.4994189070 |
| 25 | 0.4999404636 | 0.4997618988 | 0.4994644390 |
| 26 | 0.4999449550 | 0.4997798578 | 0.4995048228 |
| 27 | 0.4999489566 | 0.4997958592 | 0.4995408060 |
| 28 | 0.4999525372 | 0.4998101776 | 0.4995730054 |
| 29 | 0.4999557540 | 0.4998230406 | 0.4996019336 |
| 30 or greater | 0.4999586544 | 0.4998346392 | 0.4996280190 |

The control device 11 determines whether or not an elapsed time from application of a voltage has reached a prescribed time. When the elapsed time is determined to have reached the prescribed time, the current value of that time is accepted as a stabilized current value, and stored in the storage unit. On the other hand, when the elapsed time is determined not to have reached the prescribed time, stability of the current value is determined again after the prescribed time Δt elapsed.

It is preferred that the measurement device 11 obtain the average stable current value by averaging a plurality of current values that are determined to have been stable. The measurement device 11 obtains an electrical characteristic of the sample 1 based on a current value that is determined to have been stable. The electrical characteristic is, for example, a current-voltage characteristic (hereinafter appropriately referred to as an “I-V characteristic”). In addition, the measurement device 11 may be set to further obtain, as the electrical characteristic, at least one kind selected from a group that includes an open voltage Voc, a short-circuit current Isc, a maximum output value Pmax, a maximum output voltage Vmax, a maximum output current value Imax, a series resistance value Rs, a parallel resistance value Rsh, a fill factor FF, and the like.

The control device 11 stores the obtained electrical characteristic in, for example, the storage unit. In addition, the control device 11 may cause the obtained electrical characteristic to be output to the display unit or a printing unit. The control device 11 may cause the obtained electrical characteristic to be transmitted to an external terminal device or the like via a network or the like.

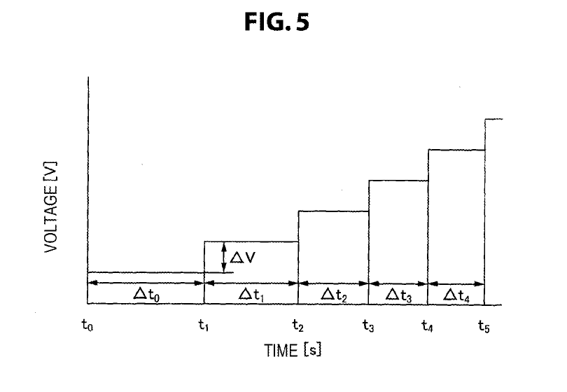

FIG. 5 is a diagram showing a time dependency of an applied voltage. The control device 11 controls the four-quadrant power source 12 such that the voltage is applied in a step form (staircase form). The control device 11 causes the voltage to be static point by point so as to have stability of a current value in each point of the voltage being static point by point. For this reason, widths of steps of the voltage applied in the step form (staircase form) differ for each voltage.

### (5) Measurement Method of an I-V Curve

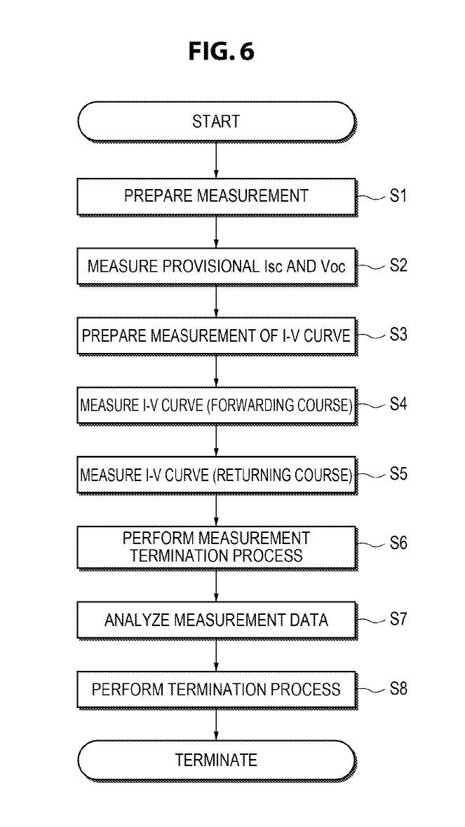

FIG. 6 is a flowchart for describing a measurement method of an I-V curve of the measurement device having the configuration described above. The measurement method of the I-V curve has processes of Steps S1 to S8 as shown in FIG. 6. Note that the processes of Step S5 and Step S7 may be set to be executed according to necessity of a user. Hereinbelow, the processes of Steps S1 to S8 will be described in order.

### <Measurement Preparation>

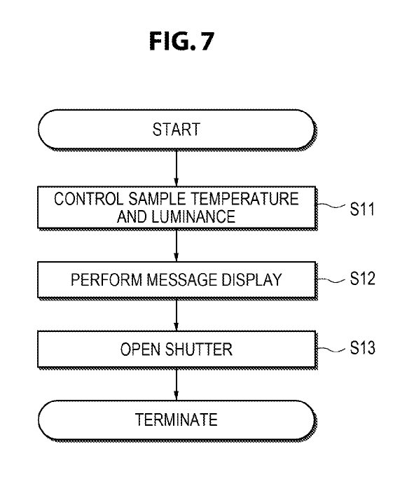

FIG. 7 is a flowchart for describing a process of measurement preparation (Step S1) shown in FIG. 6.

First, in Step S11, separate feedback control is performed so that a temperature of a sample and luminance are constant throughout measurement. Next, in Step S12, a message that prompts a user to set the sample 1 to be tested on a test table of the thermostatic bath 13 is displayed on the display unit 24. Next, in Step S13, a shutter of the light irradiator 14 is opened.

<Measurement of Provisional Isc′ and Voc′>

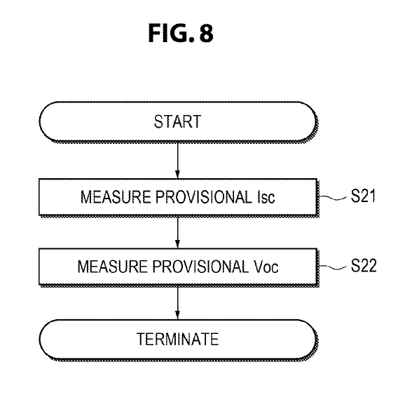

FIG. 8 is a flowchart for describing a process of measuring a provisional short-circuit current value Isc and open voltage value Voc (Step S2) shown in FIG. 6.

First, in Step S21, the four-quadrant power source 12 is set to be in a voltage regulating (potentiostatic) mode, a set voltage V=0 (short-circuit state) is set, and stabilization of the current is awaited. When the current is in a stable state, a value thereof is accepted as a provisional short-circuit current value Isc′. Next, in Step S22, the four-quadrant power source 12 is set to be in a current regulating (galvanostatic) mode, a set current I=0 (open state) is set, and stabilization of a voltage is awaited. When the voltage is in a stable state, a value thereof is accepted as a provisional open voltage value Voc′.

### <I-V Curve Measurement Preparation>

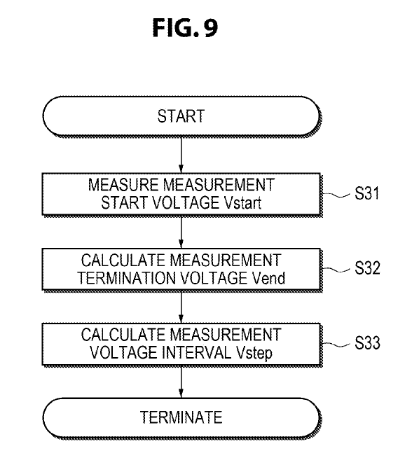

FIG. 9 is a flowchart for describing a process of I-V curve measurement preparation (Step S3) shown in FIG. 6.

First, in Step S31, while the four-quadrant power source 12 is maintained in the current regulating (galvanostatic) mode, a set current I=−a×Isc′ (a is, for example, 0.3) is set, and then stabilization of the voltage is awaited. When the voltage is in a stable state, a value thereof is accepted as a measurement termination voltage value Vend. Next, in Step S32, using the following formula, a measurement start voltage value Vstart=−b×Voc′ (b is, for example, 0.15) is calculated. Next, in Step S33, using the following formula, a measurement voltage interval Vstep=(Vend−Vstart)/n (n is the number of measurement points, for example, 10) is calculated.

### <I-V Curve Measurement (Forwarding Course)>

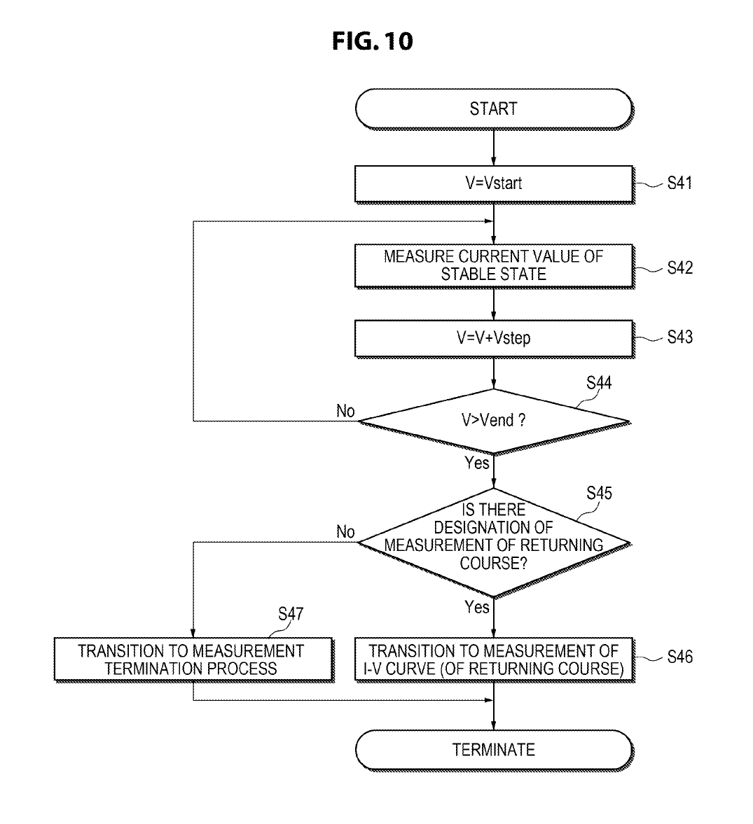

FIG. 10 is a flowchart for describing a process of I-V curve measurement (forwarding course: Step S4) shown in FIG. 6.

First, in Step S41, the measurement start voltage value Vstart is replaced for a variable V. Next, in Step S42, the four-quadrant power source 12 is set to be in a voltage regulating (potentiostatic) mode, a set voltage is set to V, and stabilization of the current is awaited. When the current is in the stable state, a current value of that time is accepted as a current value of the stable state.

Next, in Step S43, the measurement voltage interval Vstep is added to the set voltage V. Next, in Step S44, it is determined whether or not the set voltage V exceeds the measurement termination voltage value Vend. When the set voltage V is determined to exceed the measurement termination voltage value Vend in Step S44, the process transitions to Step S45. On the other hand, when the set voltage V is determined not to exceed the measurement termination voltage value Vend in Step S44, the process returns to Step S42.

Next, in Step S45, it is determined whether or not a user has designated returning course measurement in advance. When, in Step S45, the user is determined to have designated the returning course measurement in advance, the process transitions to returning course I-V curve measurement (Step S5) in Step S46. On the other hand, when the user is determined not to have designated the returning course measurement in advance in Step S45, the process transitions to a measurement termination process (Step S6) in Step S47.

### <I-V Curve Measurement (Retuning Course)>

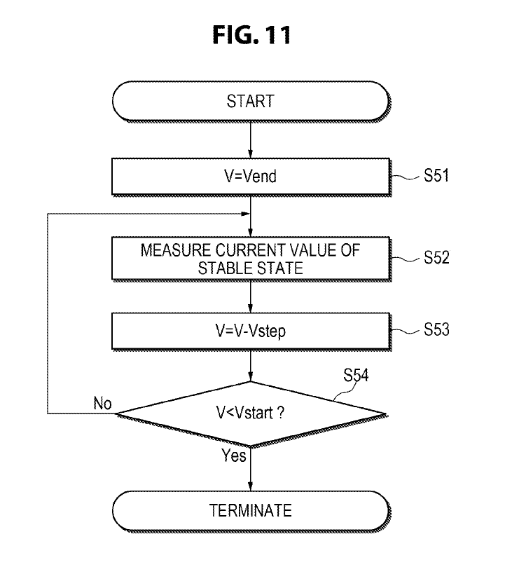

FIG. 11 is a flowchart for describing a process of I-V curve measurement (returning course: Step S5) shown in FIG. 6.

First, in Step S51, the measurement start voltage value Vend is replaced for the variable V. Next, in Step S52, the four-quadrant power source 12 is set to be in a voltage regulating (potentiostatic) mode, a set voltage is set to V, and stabilization of the current is awaited. When the current is in the stable state, a current value of that time is accepted as a current value of the stable state.

Next, in Step S53, the measurement voltage interval Vstep is subtracted from the set voltage V. Next, in Step S54, it is determined whether or not the set voltage V is smaller than the measurement termination voltage value Vstart. When the set voltage V is determined to be smaller than the measurement termination voltage value Vend in Step S54, the process is terminated. On the other hand, when the set voltage V is determined not to be smaller than the measurement termination voltage value Vend in Step S54, the process returns to Step S52.

### <Measurement Termination Process>

In the measurement termination process, the shutter of the light irradiator 14 is closed.

### <Measurement Data Analysis>

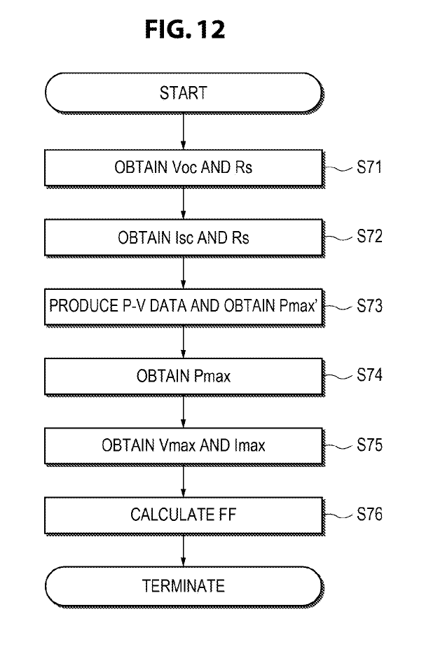

FIG. 12 is a flowchart for describing a process of measurement data analysis (Step S7) shown in FIG. 6. Note that the process of measurement data analysis to be described below is performed in forwarding and returning courses separately.

First, in Step S71, from the measured I-V data, only a plot in a current range [−a×Isc′, a×Isc′] is extracted and is made to fit a quadratic expression, the intersection with a voltage axis is analytically obtained, and the result is accepted as an open voltage value Voc. In addition, the slope at the intersection with the voltage axis is obtained, and the result is accepted as a series resistance value Rs.

Next, in Step S72, from the measured I-V data, only a plot in a current range [−b×Voc′, b×Voc′] is extracted and is made to fit a linear expression, the intersection with a current axis is analytically obtained, and the result is accepted as a short-circuit current value Isc. In addition, the slope at the intersection with the current axis is obtained, and the result is accepted as a parallel resistance value Rsh.

Next, in Step S73, with regard to all plots of the measured I-V data, P-V data is created using a formula P=I×V. In addition, a maximum value among obtained P values is set to be Pmax′.

Next, in Step S74, among the obtained P-V data, only a plot in an output range [c×Pmax′, Pmax′] (c is, for example, 0.9) is extracted and made to fit a cubic expression, a point closest to Pmax′ among points at which the slope of the differentiation is zero is obtained, and the value is accepted as the maximum output value Pmax.

Next, in Step S75, a voltage value obtained by replacing the Pmax value for the obtained cubic expression is accepted as the maximum output voltage Vmax. In addition, using the following formula, the maximum output current value Imax=Pmax/Vmax is calculated.

Next, in Step S76, using the following formula, the fill factor FF=Pmax/(Voc×Isc) is calculated.

### <Termination Process>

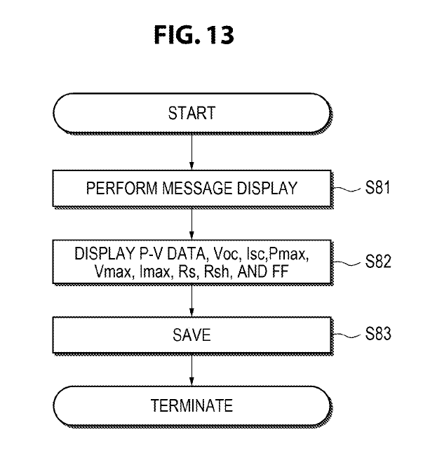

FIG. 13 is a flowchart for describing process termination (Step S8) shown in FIG. 6.

First, in Step S81, the message that prompts the user termination of measurement is displayed on the display unit 24.

Next, in Step S82, the measured I-V data, the P-V data obtained from analysis, the open voltage Voc, the short-circuit current Isc, the maximum output value Pmax, the maximum output Vmax, the maximum output current value Imax, the series resistance value Rs, the parallel resistance value Rsh, and the fill factor FF are displayed, and further in Step S83, the pieces of the data are saved in a file or the like stored in a storage unit such as an HDD 28.

### (6) Determination Method of a Current Value and a Voltage Value of a Stable State

There are four determination methods (first to fourth determination methods) as follows as determination methods of the short-circuit current value Isc, the open voltage value Voc, and the current value I in a stable state (method for waiting for stabilization of current values). Note that the algorithm shown below is an algorithm in the voltage regulating (potentiostatic) mode, in which “a voltage should be set and a current should be waited for,” and the technical gist of the present algorithm can also be applied to the current regulating (galvanostatic) mode. In such a case, a “voltage” and a “current” in the following description may be exchangeable. Note that one of the first to fourth determination methods is set as a default in, for example, a measurement device or a measurement program.

### (1) First Determination Method

The first determination method is a method for determining stability of a current value based on the number of reversals of a sign. In the first determination method, since stability of a current value is determined based only on the number of reversals of a sign, there is an advantage that a determination operation of stability of a current value can be simplified.

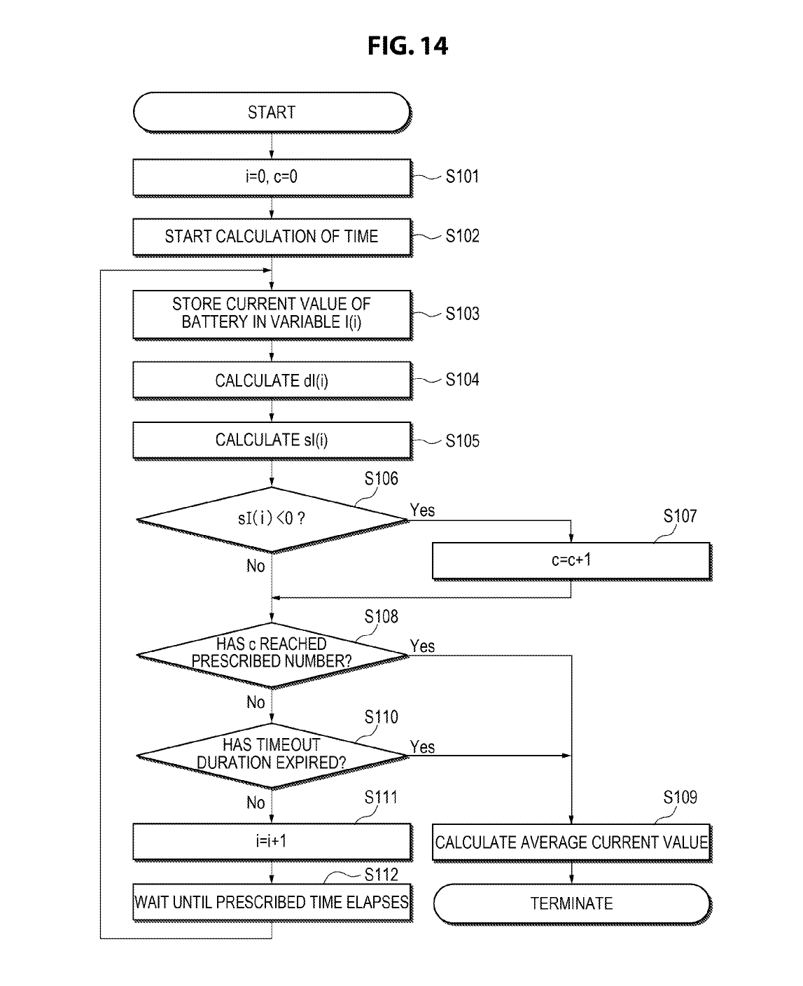

FIG. 14 is a flowchart for describing the first determination method.

First, in Step S101, definitions are made such that a loop amount counting variable i=0, and the number of current sign reversals c=0. Next, in Step S102, time starts to be measured. Next, in Step S103, a current value of the sample (for example, a solar cell element) 1 connected to the four-quadrant power source 12 is stored in a variable I(i).

Next, in Step S104, using the following formula, a current change amount changed in a fixed time interval, which is dI(i)=I(i)−I(i−1), is calculated. Next, in Step S105, using the following formula, a sign of the current change amount dI, which is sI(i)=dI(i)×dI(i−1), is calculated.

Next, in Step S106, it is determined whether or not sI(i)<0 has been satisfied. When sI(i)<0 is determined to have been satisfied in Step S106, the number of current sign reversals c increases one by one in Step S107. On the other hand, when sI(i)<0 is determined not to have been satisfied in Step S106, the process transitions to Step S108.

Next, in Step S108, it is determined whether or not the number of current sign reversals c has reached a prescribed number (for example, 10 times). When the number of current sign reversals c is determined to have reached the prescribed number in Step S108, the average current value is calculated in Step S109. For example, the average current value of the latest n current values (for example, when n=4, the average value of I(i−3), I(i−2), I(i−1), and I(i)) is calculated, and the result is accepted as a current value of a stable state. On the other hand, when the number of current sign reversals c is determined not to have reached the prescribed number in Step S108, the process transitions to Step S110.

Next, in Step S110, it is determined whether or not a prescribed time-out duration (for example, 60 seconds) has expired from the start of measurement of time. When the prescribed time-out duration is determined to have expired in Step S110, the average current value is calculated in Step S109. On the other hand, when the prescribed time-out duration is determined not to have expired in Step S110, the loop amount counting variable i increases one by one in Step S111.

Next, in Step S112, standby is performed until a prescribed time t×i (t is, for example, 20 ms) elapses from the start of measurement of time. When the elapsed time exceeds t×i, the process transitions to Step 103.

### (2) Second Determination Method

The second determination method is a method for more accurately determining stability of a current value based on a probability of reversal of the sign of a current.

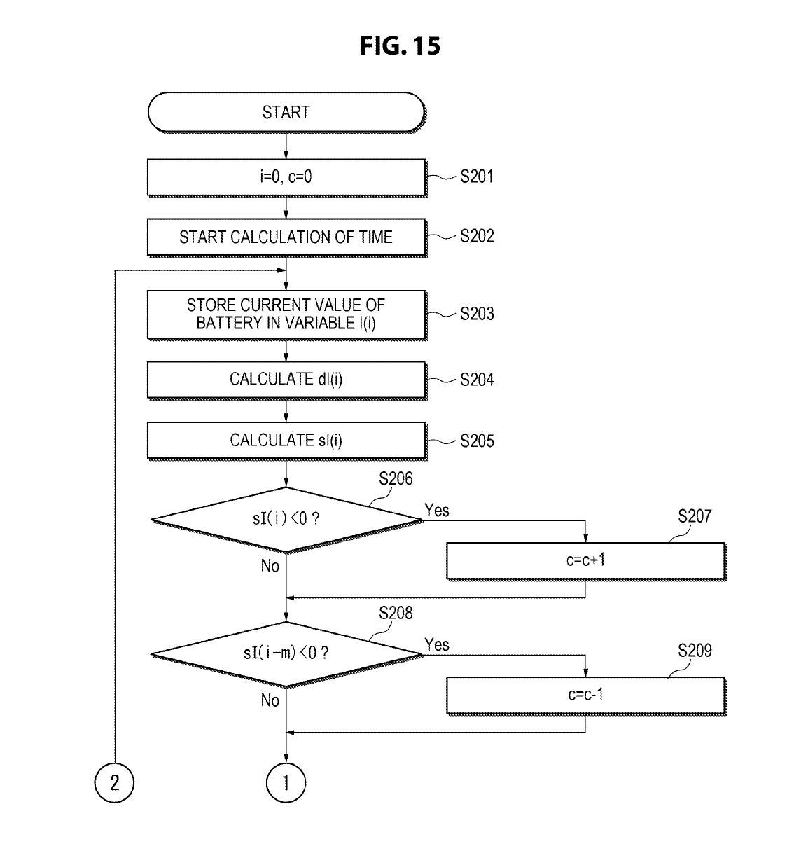

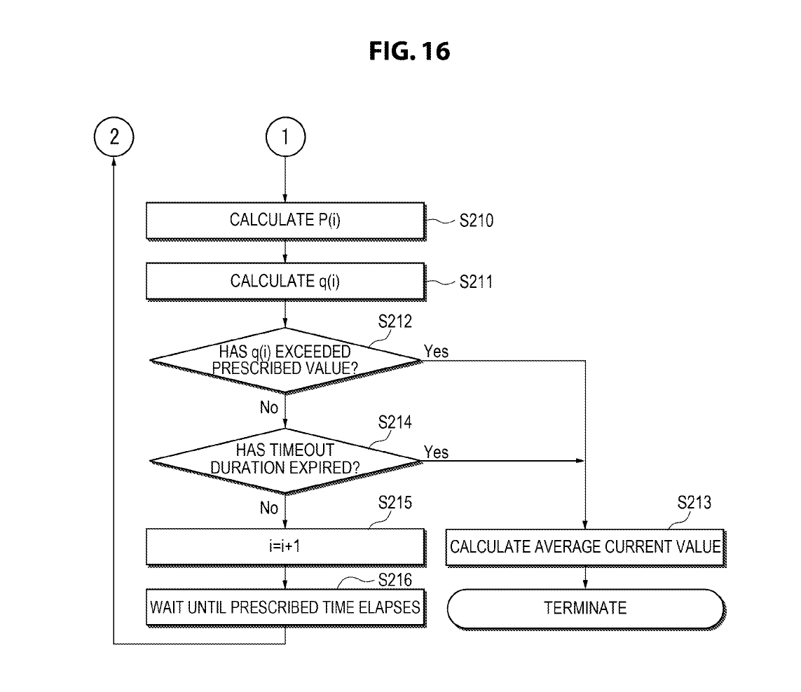

FIGS. 15 and 16 are flowcharts for describing the second determination method.

First, in Step S201, definitions are made such that the loop amount counting variable i=0 and the number of current sign reversals c=0. Next, in Step S202, time starts to be measured. Next, in Step S203, a current value of the sample (for example, a solar cell element) 1 connected to the four-quadrant power source 12 is stored in a variable I(i).

Next, in Step S204, using the following formula, a current change amount dI(i)=I(i)−I(i−1) that has changed at a constant time interval is calculated. Next, in Step S205, using the following formula, the sign of a current change amount sI(i)=dI(i)×dI(i−1) is calculated.

Next, in Step S206, it is determined whether or not sI(i)<0 has been satisfied. When sI(i)<0 is determined to have been satisfied in Step S206, the number of current sign reversals c increases one by one in Step S107. On the other hand, when sI(i)<0 is determined not to have been satisfied in Step S206, the process transitions to Step S208.

Next, in Step S208, it is determined whether or not sI(i−m)<0 has been satisfied. When sI(i−m)<0 is determined to have been satisfied in Step S208, the number of current sign reversals c decreases one by one in Step S209 (m is, for example, 10). On the other hand, when sI(i−m)<0 is determined not to have been satisfied in Step S208, the process transitions to Step S210.

Next, in Step S210, using the following formula, a probability of reversal p(i)=c/m is calculated. Next, in Step S211, using the following formula, a smoothened probability of reversal q(i)=r×q(i−1)+(1−r)×p(i) is calculated (r is, for example, 0.95).

Next, in Step S212, it is determined whether or not the smoothened probability of reversal q(i) has exceeded a prescribed value (for example, 0.258). When the probability of reversal q(i) is determined to have exceeded the prescribed value, the average current value is calculated in Step S213. For example, the average current value of the latest n values (for example, when n=4, the average value of I(i−3), I(i−2), I(i−1), and I(i)) is calculated, and the result is accepted as a current value of a stable state. On the other hand, when the probability of reversal q(i) is determined not to have exceeded the prescribed value, the process transitions to Step S214. Note that the pre-decided value is greater than or equal to 0.258 and less than 0.5. This is because q(i) that is the condition for termination as shown in Table 1 is greater than or equal to 0.258, and q(i) as shown in FIG. 2 does not exceed 0.5.

Next, in Step S214, it is determined whether or not prescribed time-out duration (for example, 60 seconds) has expired from the start of measurement of time. When the time-out duration is determined to have expired in Step S214, the average current value is calculated in Step S213. On the other hand, when the time-out duration is determined not to have expired in Step S214, the process transitions to Step S215.

Next, in Step S215, the loop amount counting variable i increases one by one. Next, in Step S216, standby is performed until a prescribed time t×i (t is, for example, 20 ms) elapses from the start of measurement of time. When the elapsed time exceeds t×i, the process transitions to Step 203.

### (3) Third Determination Method

The third determination method is a more correct determination method that utilizes accuracy that the measurement device has, without using an approximation function.

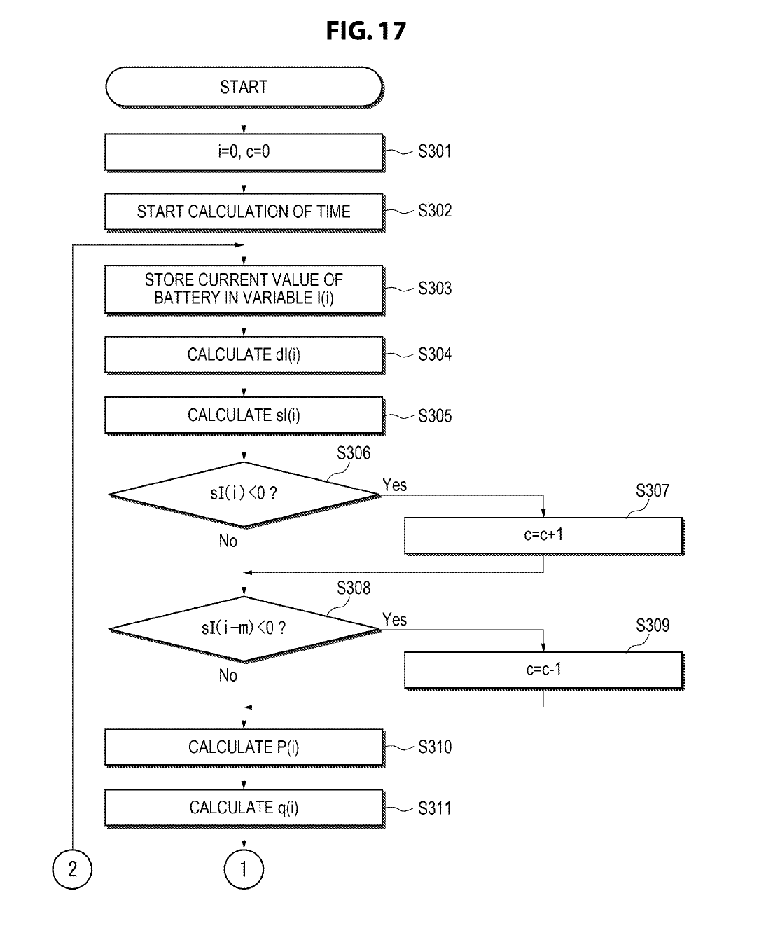

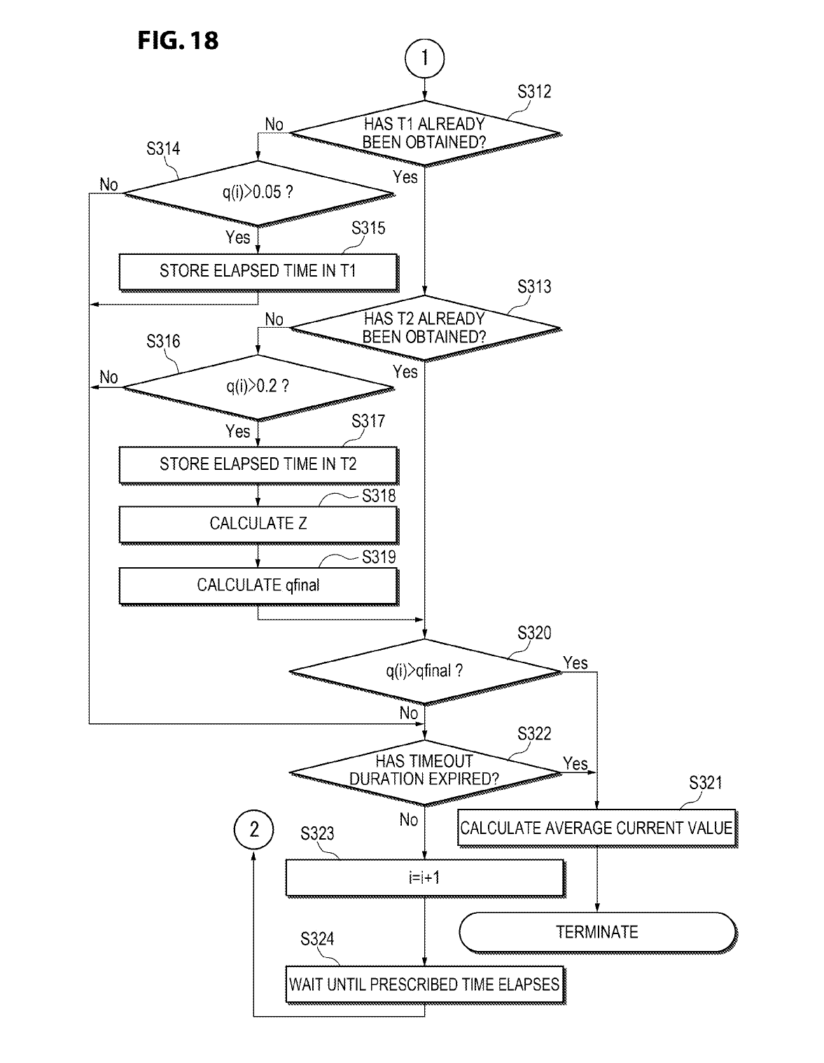

FIGS. 17 and 18 are flowcharts for describing the third determination method.

First, in Step S301, definitions are made such that the loop amount counting variable i=0 and the number of current sign reversals c=0. Next, in Step S302, time starts to be measured. Next, in Step S303, a current value of the sample (for example, a solar cell element) 1 connected to the four-quadrant power source 12 is stored in a variable I(i).

Next, in Step S304, using the following formula, a current change amount changed in a fixed time interval, which is dI(i)=I(i)−I(i−1), is calculated. Next, in Step S305, using the following formula, a sign of the current change amount, which is sI(i)=dI(i)×dI(i−1), is calculated.

Next, in Step S306, it is determined whether or not sI(i)<0 has been satisfied. When sI(i)<0 is determined to have been satisfied in Step S306, the number of current sign reversals c increases one by one in Step S307. On the other hand, when sI(i)<0 is determined not to have been satisfied in Step S306, the process transitions to Step S308.

Next, in Step S308, it is determined whether or not sI(i−m)<0 has been satisfied. When sI(i−m)<0 is determined to have been satisfied in Step S308, the number of current sign reversals c decreases one by one (m is, for example, 10). On the other hand, when sI(i−m)<0 is determined not to have been satisfied in Step S308, the process transitions to Step S310.

Next, in Step S310, using the following formula, a probability of reversal p(i)=c/m is calculated. Next, in Step S311, using the following formula, a smoothened probability of reversal q(i)=r×q(i−1)+(1−r)×p(i) is calculated (r is, for example, 0.95).

Next, in Step S312, it is determined whether or not an elapsed time T1 has already been obtained. Here, the elapsed time T1 is an elapsed time in which the smoothened probability of reversal q(i) exceeds 0.05 for the first time.

When the elapsed time T1 is determined to have already been obtained in Step S312, the process transitions to Step S313. On the other hand, when the elapsed time T1 is determined not to have been obtained in Step S312, the process transitions to Step 314.

When the process transitions to Step 314, it is determined whether or not the smoothened probability of reversal q(i) has exceeded 0.05 in Step S314. When the smoothened probability of reversal q(i) is determined to have exceeded 0.05 in Step S314, the elapsed time T1 is saved in the storage unit in Step S315. Then, the process transitions to Step S322. On the other hand, when the smoothened probability of reversal q(i) is determined not to have exceeded 0.05 in Step S314, the process transitions to Step S322.

When the process transitions to Step S313, it is determined whether or not an elapsed time T2 has already been obtained in Step S313. Here, T2 is an elapsed time in which the smoothened probability of reversal q(i) exceeds 0.20 for the first time. When the elapsed time T2 is determined to have already been obtained in Step S313, the process transitions to Step S320. On the other hand, when the elapsed time T2 is determined not to have been obtained in Step S313, the process transitions to Step S316.

When the process transitions to Step S316, it is determined whether or not the smoothened probability of reversal q(i) has exceeded 0.2 in Step S316. When the smoothened probability of reversal q(i) is determined to have exceeded 0.2 in Step S316, the elapsed time T2 is saved in the storage unit in Step S317. Next, in Step S318, using the following formula, the termination condition parameter Z=(T2−T1)/t is calculated. Next, in Step S319, a probability of termination q_final is obtained from the termination condition parameter Z with reference to the conversion table (for example, Table 1) described above. Then, the process transitions to Step S320. On the other hand, when the smoothened probability of reversal q(i) is determined not to have exceeded 0.2 in Step S316, the process transitions to Step S322.

Next, in Step S320, it is determined whether or not the smoothened probability of reversal q(i) is greater than q_final. When q(i) is determined to be greater than q_final in Step S320, the average current value is calculated in Step S321. For example, the average current value of the latest n values (for example, when n=4, the average value of I(i−3), I(i−2), I(i−1), and I(i)) is calculated, and the result is accepted as a current value of a stable state. On the other hand, when q(i) is determined not to be greater than q_final in Step S320, the process transitions to Step S322.

Next, in Step S322, it is determined whether or not a prescribed time-out duration (for example, 60 seconds) has expired from the start of measurement of time. When the time-out duration is determined to have expired in Step S322, the average current value is calculated in Step S321. On the other hand, when the prescribed time-out duration is determined not to have expired in Step S322, the process transitions to Step S323.

Next, in Step S323, the loop amount counting variable i increases one by one. Next, in Step S324, standby is performed until a prescribed time t×i (t is, for example, 20 ms) elapses from the start of measurement of time. Then, when the elapsed time exceeds t×i, the process transitions to Step 303.

### (4) Fourth Determination Method

The fourth determination method is a more correct determination method that utilizes accuracy that the measurement device has using an approximation function.

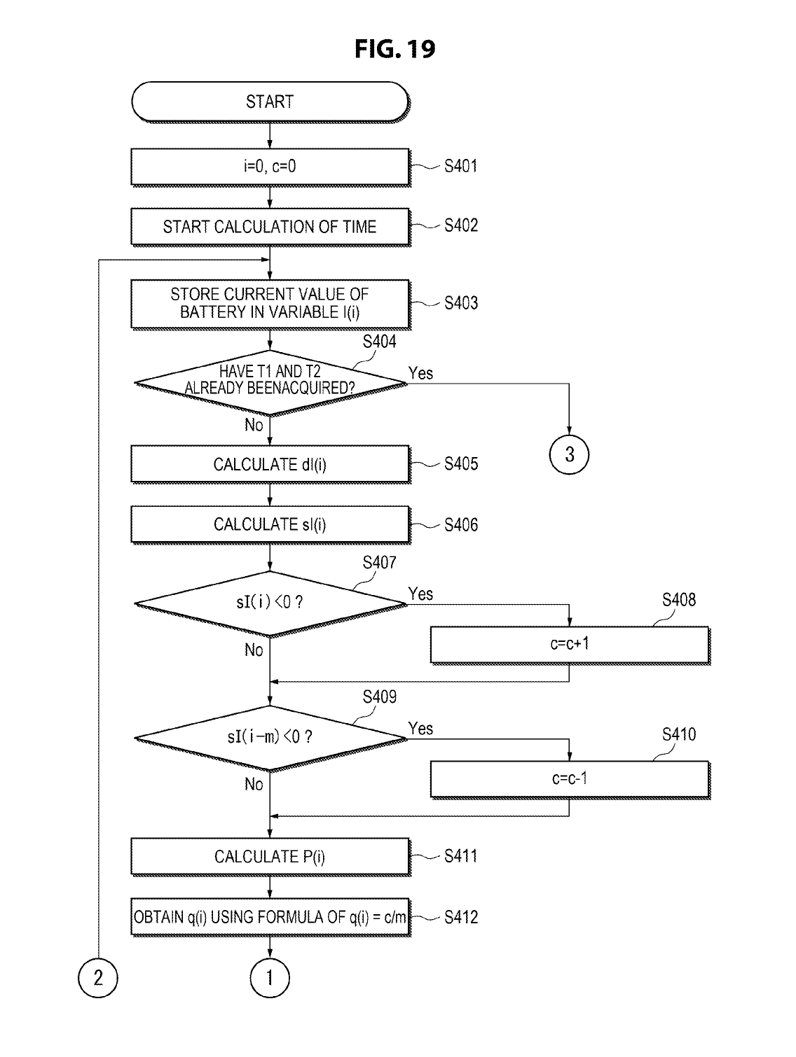

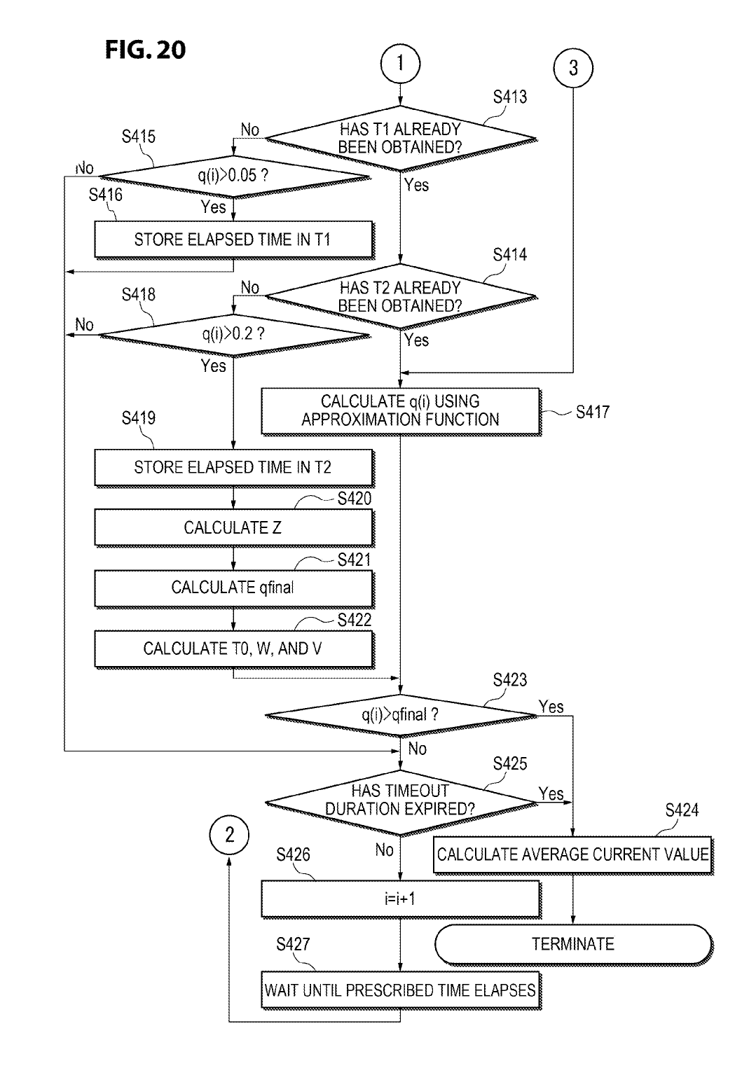

FIGS. 19 and 20 are flowcharts for describing the fourth determination method.

First, in Step 401, definitions are made such that a loop amount counting variable i=0, and the number of current sign reversals c=0. Next, in Step S402, time starts to be measured. Next, in Step S403, a current value of the sample (for example, a solar cell element) 1 connected to the four-quadrant power source 12 is stored in a variable I(i).

Next, in Step 404, it is determined whether or not elapsed times T1 and T2 have already been acquired. When the elapsed times T1 and T2 are determined to have already been acquired in Step S404, the process transitions to Step S417. When the elapsed times T1 and T2 are determined not to have been acquired in Step S404, the process transitions to Step S405.

Next, in Step S405, using the following formula, a current change amount changed in a fixed time interval, which is dI(i)=I(i)−I(i−1), is calculated. Next, in Step S406, using the following formula, a sign of the current change amount, which is sI(i)=dI(i)×dI(i−1), is calculated.

Next, in Step S407, it is determined whether or not sI(i)<0 has been satisfied. When sI(i)<0 is determined to have been satisfied in Step S407, the number of current sign reversals c increases one by one in Step S408. On the other hand, when sI(i)<0 is determined not to have been satisfied in Step S407, the process transitions to Step S409.

Next, in Step S409, it is determined whether or not sI(i−m)<0 has been satisfied. When sI(i−m)<0 is determined to have been satisfied in Step S409, the number of current sign reversals c decreases one by one in Step S410 (m is, for example, 10). On the other hand, when sI(i−m)<0 is determined not to have been satisfied in Step S409, the process transitions to Step S411.

Next, in Step S411, using the following formula, a probability of reversal p(i)=c/m is calculated. Next, in Step S412, using the following formula, a smoothened probability of reversal q(i)=r×q(i−1)±(1−r)×p(i) is calculated (r is, for example, 0.95).

Next, in Step S413, it is determined whether or not an elapsed time T1 has already been obtained. Here, the elapsed time T1 is an elapsed time in which the smoothened probability of reversal q(i) exceeds 0.05 for the first time.

When the elapsed time T1 is determined to have already been obtained in Step S413, the process transitions to Step S414. On the other hand, when the elapsed time T1 is determined not to have been obtained in Step S413, the process transitions to Step 415.

When the process transitions to Step 415, it is determined whether or not the smoothened probability of reversal q(i) has exceeded 0.05 in Step S415. When the smoothened probability of reversal q(i) is determined to have exceeded 0.05 in Step S415, the elapsed time T1 is saved in the storage unit in Step S416. Then, the process transitions to Step S425. On the other hand, when the smoothened probability of reversal q(i) is determined not to have exceeded 0.05 in Step S415, the process transitions to Step S425.

When the process transitions to Step S414, it is determined whether or not the elapsed time T2 has already been obtained in Step S414. Here, T2 is an elapsed time in which the smoothened probability of reversal q(i) exceeds 0.20 for the first time. When the elapsed time T2 is determined to have already been obtained in Step S414, the value of q(i)=(t×i−T0)^{w}/[V+2(t×i−T0)^{w}] is calculated using the approximation function in Step S417. Then, the process transitions to Step S423. On the other hand, when the elapsed time T2 is determined not to have been obtained in Step S414, the process transitions to Step S418.

When the process transitions to Step S418, it is determined whether or not the smoothened probability of reversal q(i) has exceeded 0.2 in Step S418. When the smoothened probability of reversal q(i) is determined to have exceeded 0.2 in Step S418, the elapsed time T2 is saved in the storage unit in Step S419. Next, in Step S420, using the following formula, a termination condition parameter Z=(T2−T1)/t is calculated. Next, in Step S421, a probability of termination q_final is obtained from the termination condition parameter Z with reference to the conversion table (for example, Table 1) described above. Next, in Step S422, three coefficients of the approximation function which are T0=3.438T1−2.438T2, W=1.792/[ln(T2−T0)−ln(T1−T0)], and V=18(T1−T0)^{w} are calculated. On the other hand, when the smoothened probability of reversal q(i) is determined not to have exceeded 0.2 in Step S418, the process transitions to Step S425.

Next, in Step S423, it is determined whether or not the smoothened probability of reversal q(i) is greater than q_final. When q(i) is determined to be greater than q_final in Step S423, the average current value is calculated in Step S424. For example, the average current value of the latest n values (for example, when n=4, the average value of I(i−3), I(i−2), I(i−1), and I(i)) is calculated, and the result is accepted as a current value of a stable state. On the other hand, when q(i) is determined not to be greater than q_final in Step S423, the process transitions to Step S425.

Next, in Step S425, it is determined whether or not a prescribed time-out duration (for example, 60 seconds) has expired from the start of measurement of time. When the prescribed time-out duration is determined to have expired in Step S425, the average current value is calculated in Step S424. On the other hand, when the prescribed time-out duration is determined not to have expired in Step S425, the process transitions to Step S426.

Next, in Step S426, the loop amount counting value i increases one by one. Next, in Step S327, standby is performed until a prescribed time t×i (t is, for example, 20 ms) elapses from the start of measurement of time. Then, when the elapsed time exceeds t×i, the process transitions to Step 303.

Note that the processes of the flowcharts shown in FIGS. 6 to 20 are executed by the measurement device 11 (for example, the CPU 21) or the measurement program.

### [Effect]

According to an embodiment of the present technology, stability of a current value at each point of a voltage is determined by stopping application of the voltage point by point rather than using sweeping of a voltage. Thus, reproducibility of a measurement value of the electrical characteristic can be improved (for example, the I-V curves can be made substantially the same in forwarding and returning courses), and a measurement time of the electrical characteristic can be shortened.

Even a sample with an unknown response speed can be subjected to measurement of an electrical characteristic without advance review.

Measurement can be performed automatically for an appropriate measurement time that is neither too long nor too short. In other words, it is not necessary to worry about inaccuracy resulting from an excessively short measurement time, or a meaninglessly long measurement time.

A response speed of a cell can also be measured at the same time, if necessary.

### (7) Modification Example

In the embodiments described above, the configuration in which one of the first to fourth determination methods is set as a default for the measurement device or measurement program has been exemplified, however, a user may be able to select a desired one from the first to fourth determination methods. An example of an operation of the measurement device or measurement program adopting such a configuration will be described below.

First, during the process of the measurement preparation (Step S1), the first to the fourth determination methods are displayed on the display unit 24 as first to fourth modes, and the user is prompted to select a mode. When the user selects a desired mode from the first to fourth modes using the input unit 26, the selected mode is set in the measurement device. The mode selected by the user is stored in the RAM 23 and/or the HDD 28 serving as a storage unit.

In steps of “measurement of provisional Isc and Voc” (Step S2), “I-V curve measurement preparation” (Step S3), “I-V curve measurement (forwarding course)” (Step S4), and “I-V curve measurement (returning course)” (Step S5), a stabilized current or voltage is determined according to the mode selected by the user.

Note that, among the “measurement of provisional Isc and Voc” (Step S2), “I-V curve measurement preparation” (Step S3), “I-V curve measurement (forwarding course)” (Step S4), and “I-V curve measurement (returning course)” (Step S5), the “I-V curve measurement (forwarding course)” (Step S4) and “I-V curve measurement (returning course)” (Step S5) are set in modes that can be selected by the user, and others may be set as a default.

In addition, time taken to determine that a current value is stabilized at each voltage static point by point may be set to be stored in the storage unit. The time stored in that manner may be set to be displayed on a screen as a graph or the like in the process of measurement data analysis (Step S7). By performing such a process, voltage dependency of the response speed of the sample 1 can be checked.

### EXAMPLES

Hereinafter, the present technology will be described in detail using examples, however, the present technology is not limited only to the examples.

The examples and comparative examples will be described in the following order.

1. Comparison of an electrical characteristic depending on measurement methods

2. Voltage dependency of a response speed

3. Relationship of measurement methods and a response speed of a battery

### <1. Comparison of an Electrical Characteristic Depending on Measurement Methods>

Samples 1 and 2 used in Examples 1-1 to 2-2 and Comparative examples 1-1 to 2-2 were produced as follows.

### (Sample 1)

First, an ITO film with a thickness of 100 nm was formed as a transparent conductive layer on a glass substrate using a sputtering method, and a transparent conductive substrate was thereby obtained. Next, on the transparent conductive substrate, a porous semiconductor layer retaining a sensitized dye was formed in the following manner.

First, the following materials underwent a dispersion process for 16 hours using a bead disperser, and a titanium oxide dispersion solution was thereby prepared.

Titanium oxide fine particles: 5 g of P25 manufactured by Nippon Aerosil Co., Ltd.

Solvent: 45 g of ethanol

Dispersant: 0.5 g of 3,5-dimethyl-1-hexine-3-ol

Next, the prepared titanium oxide dispersion solution was coated on the transparent conductive layer using a screen printing method, then a coating film was thereby formed, which was burned in an oven for one hour under a temperature environment of 500° C., and the porous semiconductor layer was thereby formed.

Next, the porous semiconductor layer was immersed in a dye solution having the following composition to cause the sensitizing dye to be adsorbed thereon. Then, the excess sensitizing dye was washed using ethanol and dried, and a porous semiconductor retaining a photosensitizing dye was thereby formed.

Sensitizing dye: 25 mg of cis-bis(isothiocyanato)bis(2,2′-bipyridyl-4,4′-dicarboxylato)ruthenium(II) bi-tetrabutylammonium complex (the common name of which is N719)

Solvent: 50 ml of ethanol

Next, the transparent conductive substrate on which the porous semiconductor layer was formed and a transparent conductive substrate on which a counter electrode was formed were disposed to face each other, and then sealed together using a spacer made of a resin film and an acryl-based ultraviolet curable resin. Accordingly, a liquid injectable space was formed between both substrates. As the spacer made of a resin film, a film with a thickness of 25 μm (made by Du Pont-Mitsui Polychemicals Co., Ltd., trade name: Himilan) was used.

Next, an electrolytic solution having the following composition was vacuum-injected to the liquid injectable space, and an electrolyte layer was thereby formed. In the manner described above, an intended dye-sensitized solar cell was obtained. Hereinbelow, the electrolytic solution having the following composition will be referred to as an “organic-based electrolytic solution.”

1.5 g of methoxypropionitrile

0.02 g of sodium iodide

0.8 g of 1-propyl-2,3-dimethylimidasolium iodide

0.1 g of iodine

0.05 g of 4-tert-butylpyridine (TBP)

### (Sample 2)

A dye-sensitized solar cell was obtained in the same manner as the sample 1 except that an electrolytic solution having the following composition was used. Hereinbelow, the electrolytic solution having the following composition will be referred to as an “ion liquid-based electrolytic solution.”

2.0 g of a mixed solvent obtained by mixing EMImTCB and diglyme at a ratio by weight of 1:1

1.0 g of 1-propyl-3-methylimidazolium iodide

0.1 g of iodine

0.054 g of N-butylbenzimidazole (NBB)

Here, EMImTCB is 1-ethyl-3-methylimidazolium tetracyanoborate, and diglyme is diethylene glycol dimethyl ether.

The electrical characteristics of the sample 1-3 obtained as described above were evaluated as follows.

### Example 1-1

First, the measurement device shown in FIG. 3 was prepared. As a control device of the measurement device, a PC (personal computer) was used, and in the PC, a measurement program for measuring I-V curves was stored. As the measurement program, a program that is operated according to the operation procedure of the flowchart shown in FIG. 6 was used. In addition, as a determination method of a stabilized current and voltage, the first determination method shown in FIG. 14 was used.

### (Measurement Condition)

Various measurement conditions are shown below.

Applied voltage: In a step (staircase) form with a step width of 0.05 V

Direction of voltage change: Increasing direction (an open current (Isc) state→an open voltage (Voc) state)

Measurement interval of currents: An acquisition interval of currents is 200 ms, and an acceptance interval of stable current values is decided at each measurement point using the first determination method.

Light source: Pseudo-sunlight (AM 1.5 and 100 mW/cm²)

Next, both poles of a dye-sensitized solar cell serving as a sample to be evaluated were electrically connected to a four-quadrant power source of the measurement device to evaluate electrical characteristics of the dye-sensitized solar cell. Here, the evaluated electrical characteristics are the I-V characteristic, the open voltage Voc, the short-circuit current density Jsc, the fill factor FF, the photoelectric conversion efficiency Eff., the series resistance value Rs, and the maximum output value Wpm (Pmax).

### Example 1-2

The electrical characteristics were evaluated in the same manner as in Example 1-1 except that the direction of current change was changed to a decreasing direction (an open voltage (Voc) state→an open current (Isc) state).

### Comparative Example 1-1

The electrical characteristics were evaluated in the same manner as in Example 1-1 except that a measurement program of the related art was used as the measurement program. Here, the measurement program of the related art refers to a measurement program for measuring the electrical characteristics with constant-speed sweeping, without making a voltage static point by point.

### (Measurement Condition)

Various measurement conditions are shown below.

Application voltage: Constant-speed sweeping at a sweeping speed of 15 mV/s

Measurement time: About 60 seconds

Direction of voltage change: Increasing direction (the open current (Isc) state the open voltage (Voc) state)

Light source: Pseudo-sunlight (AM 1.5 and 100 mW/cm²)

### Comparative Example 1-2

The electrical characteristics were evaluated in the same manner as in Comparative Example 1-1 except that the direction of voltage change was changed to a decreasing direction (the open voltage (Voc) state→the open current (Isc) state).

### Example 2-1

The electrical characteristics were evaluated in the same manner as in Example 1-1 except that the sample 2 was used as a sample to be evaluated.

### Example 2-2

The electrical characteristics were evaluated in the same manner as in Example 1-2 except that the sample 2 was used as a sample to be evaluated.

### Comparative Example 2-1

The electrical characteristics were evaluated in the same manner as in Comparative Example 1-1 except that the sample 2 was used as a sample to be evaluated.

### Comparative Example 2-2

The electrical characteristics were evaluated in the same manner as in Comparative Example 1-2 except that the sample 2 was used as a sample to be evaluated.

### (Result)

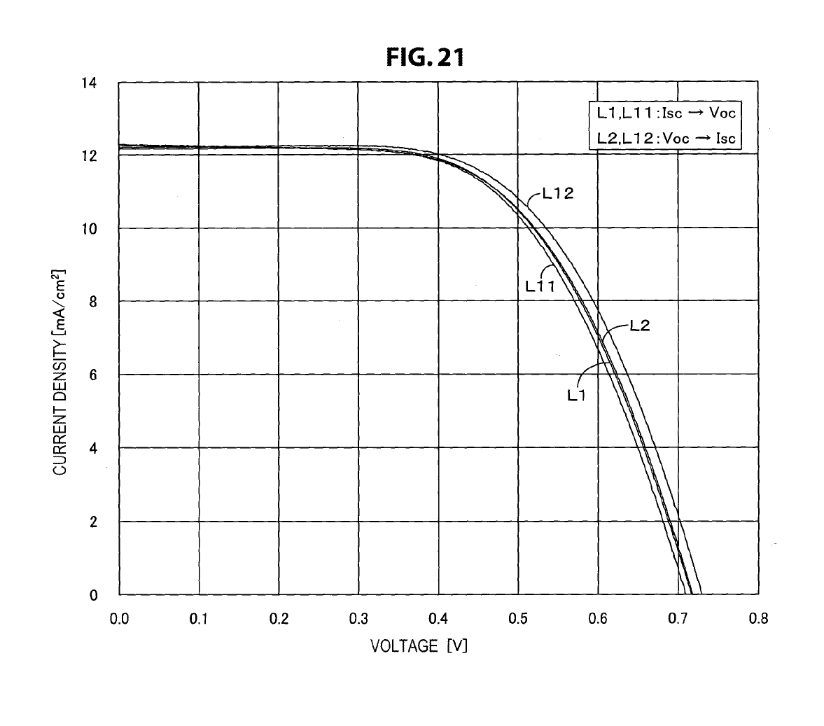

FIG. 21 shows the I-V characteristics obtained using the measurement methods of Examples 1-1 and 1-2 and Comparative examples 1-1 and 1-2. Note that, in FIG. 21, L1 and L2 are I-V curves respectively obtained using the measurement methods of Example 1-1 and Example 1-2. In addition, L11 and L12 are I-V curves respectively obtained using the measurement methods of Comparative example 1-1 and Comparative example 1-2.

Table 2 shows evaluation results from the measurement methods of Examples 1-1 and 1-2, and Comparative examples 1-1 and 1-2.

TABLE 2

| | Direction of voltage | Voc | Jsc | FF | Eff. | Rs. | Wpm |
|---|---|---|---|---|---|---|---|
| | increase and decrease | [V] | [mA/cm²] | [%] | [%] | [Ω] | [mW] |
| Example 1-1 | Voltage increase (Isc→Voc) | 0.718 | 12.26 | 59.7 | 5.25 | 0.111 | 635 |
| Example 1-2 | Voltage decrease (Voc→Isc) | 0.717 | 12.01 | 60.9 | 5.25 | 0.115 | 634 |
| Comparative example | Voltage increase (Isc→Voc) | 0.709 | 12.31 | 59.4 | 5.19 | 0.113 | 627 |
| 1-1 | | | | | | | |
| Comparative example | Voltage decrease (Voc→Isc) | 0.730 | 12.21 | 60.7 | 5.41 | 0.110 | 654 |
| 1-2 | | | | | | | |

Voc: Open voltage value
Jsc: Short-circuit current density
FF: Fill factor
Eff.: Photoelectric conversion efficiency
Rs: Series resistance value
Wpm: Maximum output value

Table 3 shows differences of the evaluation results from the measurement methods of Examples 1-1 and 1-2, and Comparative examples 1-1 and 1-2.

TABLE 3

| | Direction of voltage | Δ Voc | Δ Jsc | Δ FF | Δ Eff. | Δ Rs. | Δ Wpm |
|---|---|---|---|---|---|---|---|
| | increase and decrease | [V] | [mA/cm²] | [%] | [%] | [Ω] | [mW] |
| Example 1-1 | Voltage increase (Isc→Voc) | 0.001 | 0.250 | 1.200 | 0.000 | 0.004 | 1.000 |
| Example 1-2 | Voltage decrease (Voc→Isc) | | | | | | |
| Comparative example | Voltage increase (Isc→Voc) | 0.021 | 0.100 | 1.300 | 0.220 | 0.003 | 27.000 |
| 1-1 | | | | | | | |
| Comparative example | Voltage decrease (Voc→Isc) | | | | | | |
| 1-2 | | | | | | | |

ΔVoc: Difference of open voltage values Voc
ΔJsc: Difference of short-circuit current densities Jsc
ΔFF: Difference of fill factors FF
ΔEff.: Difference of photoelectric conversion efficiencies Eff.
ΔRs: Difference of series resistance values Rs
ΔWpm: Difference of maximum output values Wpm

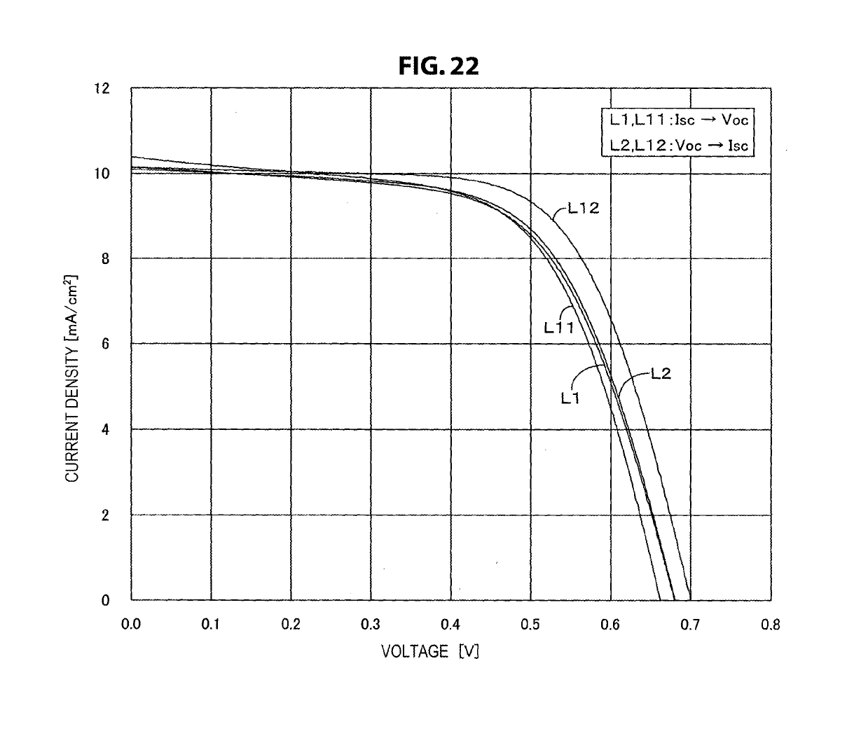

FIG. 22 shows the I-V characteristics obtained using the measurement methods of Examples 2-1 and 2-2 and Comparative examples 2-1 and 2-2. Note that, in FIG. 22, L1 and L2 are I-V curves respectively obtained using the measurement methods of Example 2-1 and Example 2-2. In addition, L11 and L12 are I-V curves respectively obtained using the measurement methods of Comparative example 2-1 and Comparative example 2-2.

Table 4 shows evaluation results from the measurement methods of Examples 2-1 and 2-2 and Comparative examples 2-1 and 2-2.

TABLE 4

| | Direction of voltage | Voc | Jsc | FF | Eff. | Rs. | Wpm |
|---|---|---|---|---|---|---|---|
| | increase and decrease | [V] | [mA/cm²] | [%] | [%] | [Ω] | [mW] |
| Example 2-1 | Voltage increase (Isc→Voc) | 0.680 | 10.15 | 62.0 | 4.28 | 0.116 | 517 |
| Example 2-2 | Voltage decrease (Voc→Isc) | 0.681 | 9.90 | 64.5 | 4.34 | 0.113 | 525 |
| Comparative example | Voltage increase (Isc→Voc) | 0.662 | 10.40 | 61.7 | 4.25 | 0.101 | 514 |
| 2-1 | | | | | | | |
| Comparative example | Voltage decrease (Voc→Isc) | 0.700 | 10.14 | 66.2 | 4.70 | 0.103 | 568 |
| 2-2 | | | | | | | |

Voc: Open voltage value
Jsc: Short-circuit current density
FF: Fill factor
Eff.: Photoelectric conversion efficiency
Rs: Series resistance value
Wpm: Maximum output value

Table 5 shows differences of the evaluation results from the measurement methods of Examples 2-1 and 2-2, and Comparative examples 2-1 and 2-2.

TABLE 5

| | Direction of voltage | Δ Voc | Δ Jsc | Δ FF | Δ Eff. | Δ Rs. | Δ Wpm |
|---|---|---|---|---|---|---|---|
| | increase and decrease | [V] | [mA/cm²] | [%] | [%] | [Ω] | [mW] |
| Example 2-1 | Voltage increase (Isc→Voc) | 0.001 | 0.250 | 2.500 | 0.060 | 0.003 | 8.000 |
| Example 2-2 | Voltage decrease (Voc→Isc) | | | | | | |
| Comparative example | Voltage increase (Isc→Voc) | 0.038 | 0.260 | 4.500 | 0.450 | 0.002 | 54.000 |
| 2-1 | | | | | | | |
| Comparative example | Voltage decrease (Voc→Isc) | | | | | | |
| 2-2 | | | | | | | |

ΔVoc: Difference of open voltage values Voc
ΔJsc: Difference of short-circuit current densities Jsc
ΔFF: Difference of fill factors FF
ΔEff.: Difference of photoelectric conversion efficiencies Eff.
ΔRs: Difference of series resistance values Rs
ΔWpm: Difference of maximum output values Wpm

### (Consideration)

The following are ascertained from FIGS. 21 and 22.

In Examples 1-1 and 1-2, the I-V curves substantially coincide. In other words, the I-V curves coincide regardless of the direction of voltage change (“Voc→Isc,” and “Isc→Voc”).

On the other hand, in Comparative examples 1-1 and 1-2, the I-V curves are different. In other words, the difference occurs in the I-V curves due to the direction of voltage change (“Voc→Isc”, and “Isc→Voc”). The difference tends to be remarkable in a region of a high voltage.

In Examples 2-1 and 2-2 in which the ion liquid-based electrolytic solution was used, the I-V curves show substantially the same fashion as in Examples 1-1 and 1-2.

In Comparative examples 2-1 and 2-2 in which the ion liquid-based electrolytic solution was used, the difference of the I-V curves caused by the direction of voltage change (“Voc→Isc”, and “Isc→Voc”) tends to be greater than in Comparative examples 2-1 and 2-2. The magnitude tends to be remarkable in a region of a high voltage. This is considered to be due to the fact that a change amount of a current is great in a region of a high voltage, and accordingly, it takes time for the current to stabilize.

The following are ascertained from Table 2 and Table 3.

The differences of the evaluation result values (ΔVoc, ΔJsc, ΔFF, ΔEff., ΔRs, and ΔPmax (Wpm)) in Examples 1-1 and 1-2 tend to be smaller than the differences of the evaluation result values of Comparative examples 1-1 and 1-2.

Particularly, the differences of the conversion efficiencies ΔEff. of both cases are distinctly different. In other words, whereas the difference ΔEff. of the conversion efficiencies Eff. of Examples 1-1 and 1-2 is 0.00%, the difference ΔEff. of the conversion efficiencies Eff. of Comparative examples 1-1 and 1-2 is 0.22%.

The differences of the evaluation result values of Examples 2-1 and 2-2 and Comparative examples 2-1 and 2-2 in which the ion liquid-based electrolytic solution was used tended to be more distinct than the differences of the evaluation result values of Examples 1-1 and 1-2 and Comparative examples 1-1 and 1-2. This is considered to be due to the fact that the ion liquid-based electrolytic solution used in Examples 2-1 and 2-2 and Comparative examples 2-1 and 2-2 has higher viscosity and lower electrical response speed than the organic-based electrolytic solution used in Examples 1-1 and 1-2 and Comparative examples 1-1 and 1-2.

### (Conclusion)

As described above, it is ascertained that, by measuring the electrical characteristics while the voltage is made to be static point by point and the state in which the current is stabilized is checked in real time without performing constant-speed sweeping, it is possible to deal with a so-called sample of a time constant and a more accurate value can be obtained.

### <2. Voltage Dependency of a Response Speed>

Samples 3 and 4 used in Examples 3-1 to 4-2 and Comparative examples 3-1 to 4-2 were produced as follows.

### (Sample 3)

The sample 3 was produced in the same manner as the sample 1 described above.

### (Sample 4)

The sample 4 was produced in the same manner as the sample 2 described above.

### Example 3-1

The sample 3 was used as a sample to be evaluated. In addition, time taken until a current was determined to be stabilized at a voltage made to be static point by point was stored in the storage unit. The electrical characteristics were evaluated by setting other conditions to be the same as in Example 1-1.

### Example 3-2

The sample 3 was used as a sample to be evaluated. In addition, time taken until a current was determined to be stabilized at a voltage made to be static point by point was stored in the storage unit. The electrical characteristics were evaluated by setting other conditions to be the same as in Example 1-2.

### Example 4-1

The electrical characteristics were evaluated by setting the sample 4 to be used as a sample to be evaluated as in Example 3-1.

### Example 4-2

The electrical characteristics were evaluated by setting the sample 4 to be used as a sample to be evaluated as in Example 3-2.

### (Result)

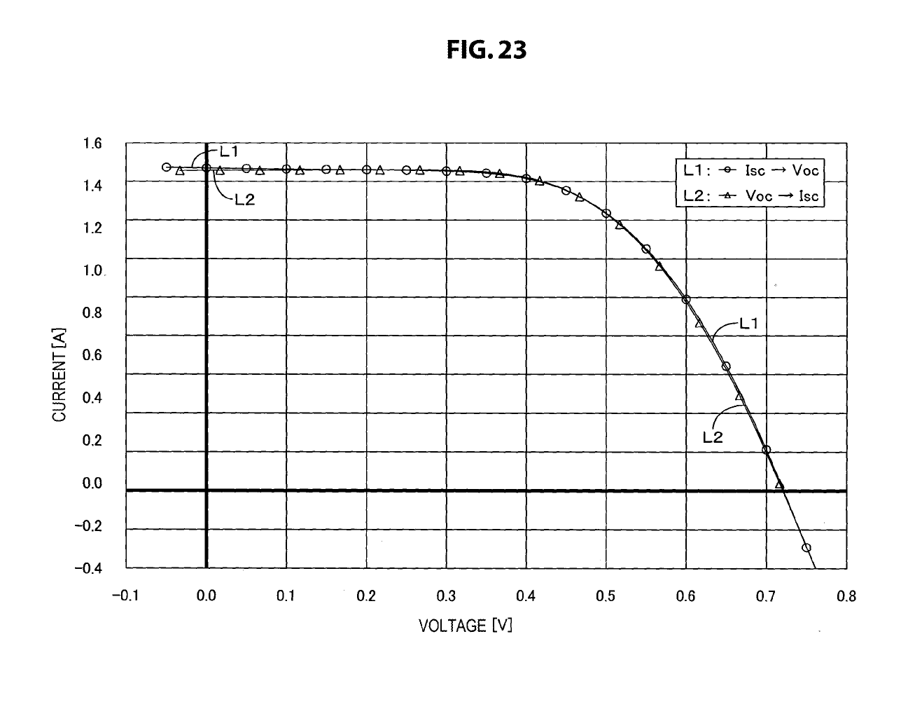

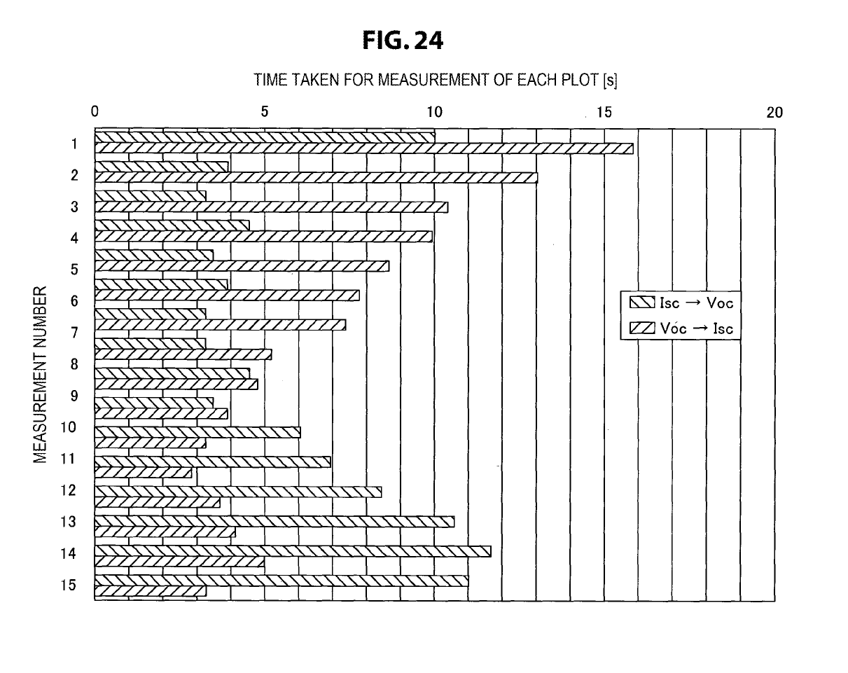

FIG. 23 is a diagram showing the I-V characteristics obtained through measurement methods of Examples 3-1 and 3-2. FIG. 24 shows times taken to measure each current value (to measure each plot) shown in FIG. 23.

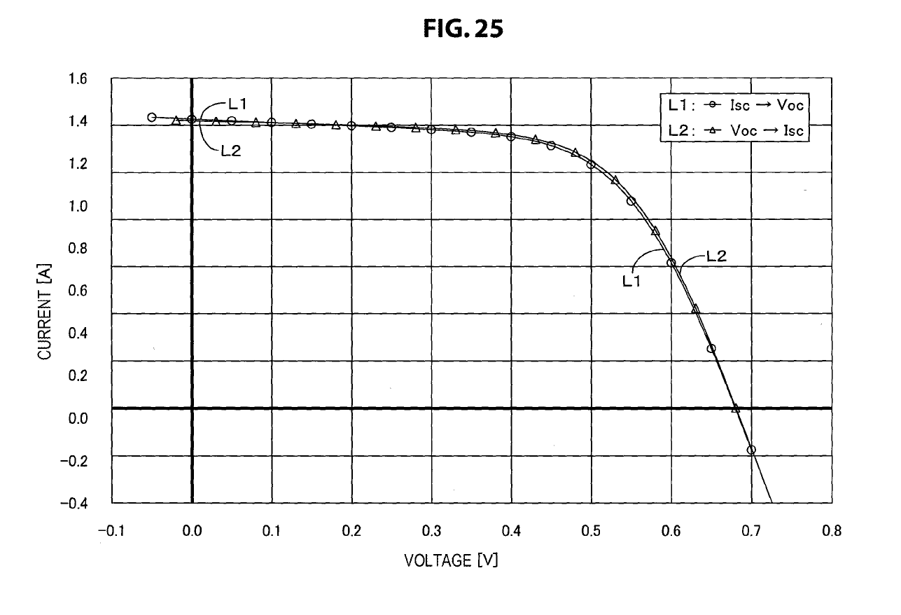

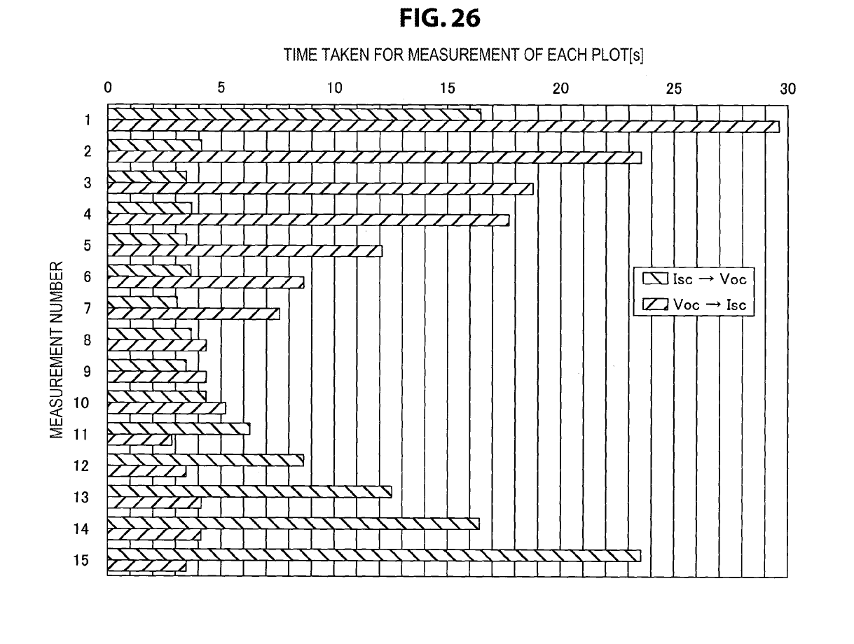

FIG. 25 is a diagram showing the I-V characteristics obtained through measurement methods of Examples 4-1 and 4-2. FIG. 26 is a diagram showing times taken to measure each current value (to measure each plot) shown in FIG. 25.

The measurement numbers of the vertical axis of FIGS. 24 and 26 are measurement numbers respectively given to each plot of the I-V curves L1 and L2 shown in FIGS. 23 and 24. Note that the measurement number of the I-V curve L1 increases in the direction of voltage increase (the open current (Isc) state→the open voltage (Voc) state). On the other hand, the measurement number of the I-V curve L2 increases in the direction of voltage decrease (the open voltage (Voc) state→the open current (Isc) state).

### (Consideration)

The following are ascertained from FIGS. 23 to 26.

A response speed is ascertained to have high voltage dependency.

A response speed tends to be slower overall when the ion liquid-based electrolytic solution is used than when the organic-based electrolytic solution is used.

### (Conclusion)

By measuring the electrical characteristics after stabilization of a current is awaited, a stabilized current can be quickly measured in a region with a low voltage. Therefore, a total measurement time of the I-V characteristic can be drastically reduced.

### <3. Relationship Between a Measurement Method and a Response Speed of a Battery>

Samples 4 to 6 used in Examples 5-1 to 5-3 and Comparative examples 3-1 to Comparative Example 3-3 were produced as follows.

### (Sample 4)

The sample 4 was produced in the same manner as the sample 1.

A dye-sensitized solar cell was obtained by setting conditions other than the above to be the same as the sample 1. Note that the difference between the maximum thickness (4485 μm) and the minimum thickness (4468 μm) in thickness in-plane distribution of the obtained dye-sensitized solar cell was 17 μm, and accordingly a substantially flat battery was configured.

### (Sample 5)

A porous semiconductor layer that retained a sensitizing dye was formed on a transparent conductive substrate using a screen printing method so as to be thick.

A dye-sensitized solar cell was obtained by setting conditions other than the above to be the same as the sample 1. Note that the difference between the maximum thickness (4508 μm) and the minimum thickness (4467 μm) in thickness in-plane distribution of the obtained dye-sensitized solar cell was 41 μm, and a battery of which the center portion swelled in a slight convex shape was thereby configured.

### (Sample 6)

A dye-sensitized solar cell was obtained by setting conditions other than pressurized injection of an electrolytic solution into a liquid injectable space between substrates to be the same as the sample 1. Note that the difference between the maximum thickness (4699 μm) and the minimum thickness (4467 μm) in thickness in-plane distribution of the obtained dye-sensitized solar cell was 232 μm, and a battery of which the center portion swelled in an extreme convex shape was thereby configured.

The sample 4 among the samples 4 to 6 obtained as described above is a cell having the highest response speed, and the sample 6 is a cell having a lowest response speed.

### Example 5-1

The electrical characteristics were evaluated in the same manner as in Example 1-2 except that the sample 4 was used as a sample to be evaluated.

### Example 5-2

The electrical characteristics were evaluated in the same manner as in Example 1-2 except that the sample 5 was used as a sample to be evaluated.

### Example 5-3

The electrical characteristics were evaluated in the same manner as in Example 1-2 except that the sample 6 was used as a sample to be evaluated.

### Comparative Example 3-1

The electrical characteristics were evaluated in the same manner as in Comparative Example 1-1 except that the sample 4 was used as a sample to be evaluated.

### Comparative Example 3-2

The electrical characteristics were evaluated in the same manner as in Comparative Example 1-1 except that the sample 5 was used as a sample to be evaluated.

### Comparative Example 3-3

The electrical characteristics were evaluated in the same manner as in Comparative Example 1-1 except that the sample 6 was used as a sample to be evaluated.

### (Result)

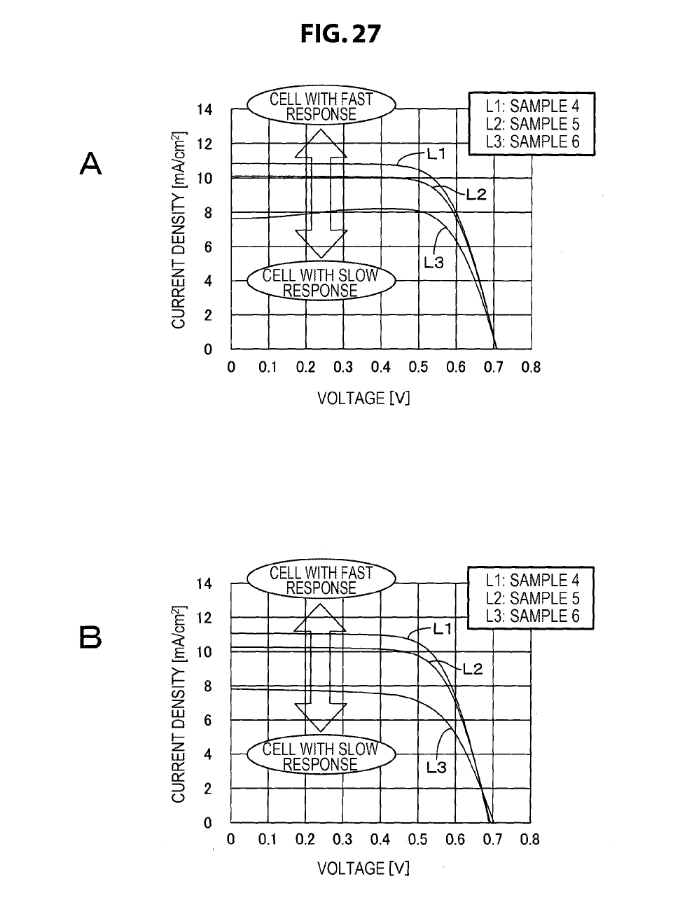

FIG. 27A shows the I-V characteristics obtained from measurement methods of Comparative examples 3-1 to 3-3. FIG. 27B shows the I-V characteristics obtained from measurement methods of Examples 5-1 to 5-3. Table 6 shows the differences of evaluation results of the measurement methods of Examples 5-1 to 5-3 and Comparative examples 3-1 to 3-3 in ratios.

Note that the ratios R_{Voc}, R_{Jsc}, R_{FF}, R_{Eff}, R_{Rs}, and R_{Wpm} shown in Table 6 represent the differences of the open voltages Voc, the short-circuit current densities Jsc, the fill factors FF, the photoelectric conversion efficiencies Eff., the series resistance values Rs, and the maximum output values Wpm (Pmax) obtained using the measurement methods of Examples 5-1 to 5-3 and the measurement methods of Comparative examples 3-1 to 3-3 in ratios. The ratios were obtained using the following specific formulas.

Ratio R_{Voc}(%)=[(Open voltage Voc obtained from the measurement methods of each comparative example/Open voltage Voc obtained from the measurement methods of each example)−1]×100

Ratio R_{Jsc}(%)=[(Short-circuit current density Jsc obtained from the measurement methods of each comparative example/Short-circuit current density Jsc obtained from the measurement methods of each example)−1]×100

Ratio R_{FF}(%)=[(Fill factor FF obtained from the measurement methods of each comparative example/Fill factor FF obtained from the measurement methods of each example)−1]×100

Ratio R_{Eff}(%)=[(Photoelectric conversion efficiency Eff. obtained from the measurement methods of each comparative example/Photoelectric conversion efficiency Eff. obtained from the measurement methods of each example)−1]×100

Ratio R_{Rs}(%)=[(Series resistance value Rs obtained from the measurement methods of each comparative example/Series resistance value Rs obtained from the measurement methods of each example)−1]×100

Ratio R_{Wpm}(%)=[(Maximum output value Wpm obtained from the measurement methods of each comparative example/Maximum output value Wpm obtained from the measurement methods of each example)−1]×100

TABLE 6

| | R_{Voc} | R_{Jsc} | R_{FF} | R_{Eff.} | R_{Rs.} | R_{Wpm} |
|---|---|---|---|---|---|---|
| | [%] | [%] | [%] | [%] | [%] | [%] |
| Sample 4 | 2.5 | 0.9 | −2.5 | 0.7 | 0.1 | 0.7 |
| Sample 5 | 1.9 | 1.8 | −1.4 | 2.3 | −7.6 | 2.3 |
| Sample 6 | 0.6 | −1.3 | 17 | 16 | −29 | 16 |

### (Consideration)

The following is ascertained from FIGS. 27A and 27B.

The I-V curves of the samples 4 and 5 having high response speeds have substantially the same shape regardless of measurement methods. On the other hand, the I-V curve of the sample 6 having a low response speed differs depending on measurement methods.

Hereinbelow, the difference will be described in detail.

In the method of the present technology for measuring the electrical characteristics after awaiting stabilization of a current by making a voltage static point by point, it is found that the I-V curves tend to monotonically increase according to the decrease of the voltage as shown in FIG. 27B. On the other hand, in the method of the related art for measuring the electrical characteristics using constant-speed sweeping, it is found that the I-V curves tend to increase first and then decrease according to the decrease of the voltage as shown in FIG. 27A.

The following is ascertained from Table 6.

The ratio R_{Voc} of the open voltage Voc and the ratio R_{Jsc} (%) of the short-circuit current density Jsc do not differ among the measurement methods, and the maximum value thereof is 2.5% at most. On the other hand, the ratio R_{FF} of the fill factor FF, the ratio R_{Eff} (%) of the photoelectric conversion efficiency Eff., the ratio R_{Rs} of the series resistance value Rs, and the ratio R_{Wpm} (%) of the maximum output value Wpm differ from the measurement methods and the maximum value thereof is about 29%.

In the measurement method of the related art, as a sample has a slower response, the fill factor FF, the photoelectric conversion efficiency Eff., and the maximum output value Wpm tend to be obtained as higher values, and the series resistance value Rs tends to be obtained as a lower value.

### (Conclusion)

As a battery has a slower response speed, the differences of the evaluation results of the electrical characteristics according to different measurement methods tend to be more distinct. Particularly, such differences are distinct in the fill factor FF, the photoelectric conversion efficiency Eff., and the maximum output value Wpm.

Hereinabove, although the embodiments and examples of the present technology have been described in detail, the present technology is not limited to the above embodiments, and can be variously modified based on the technical gist of the present technology.

For example, the configurations, methods, steps, shapes, materials, numerical values, and the like exemplified in the embodiments and examples described above are mere examples, and configurations, methods, steps, shapes, materials, numerical values, and the like different from these may be used as necessary.

In addition, the configurations, methods, steps, shapes, materials, numerical values, and the like of the embodiments and examples described above can be combined with each other as long as they do not depart from the gist of the present technology.

In addition, in the embodiments and examples described above, the operation in which the direction of voltage change is one direction (the direction of voltage increase and the direction of voltage decrease) has been described as an example, however, the direction of voltage change is not limited thereto. For example, reversals of the direction of voltage change may set to be repeated, thereby obtaining one I-V curve.

Additionally, the present technology may also be configured as below.

(1)

A measurement method for an electrical characteristic, the measurement method including:

applying a voltage to an element; and

determining stability of a current value at the applied voltage.

(2)

The measurement method for an electrical characteristic according to (1),

wherein, during application of the voltage, the voltage is applied to the element while stopping the voltage point by point, and

wherein, during determination of stability of the current value, the stability of the current value is determined at each voltage stopped point by point.

(3)

The measurement method for an electrical characteristic according to (1) or (2), wherein determining the stabilized current value includes obtaining the number of reversals of the sign of a current change amount and then determining whether or not the current has been stabilized based on the number of reversals.

(4)

The measurement method for an electrical characteristic according to (1) or (2), wherein determining the stabilized current value includes obtaining a probability of reversal of the sign of the current change amount and then determining whether or not the current has been stabilized based on the probability of reversal.

(5)

The measurement method for an electrical characteristic according to (4), wherein determining the stabilized current value includes obtaining the probability of reversal of the sign of the current change amount and then determining whether or not the probability of reversal exceeds a prescribed probability of reversal.

(6)

The measurement method for an electrical characteristic according to (4), wherein determining the stabilized current value includes obtaining an approximation function of the probability of reversal of the sign, and then determining whether or not the value of the approximation function exceeds a prescribed probability of reversal.

(7)

The measurement method for an electrical characteristic according to (6), further including:

obtaining a termination condition value from elapsed times T1 and T2 after the voltage is applied and a measurement interval Δt of the current value; and

obtaining the prescribed probability of reversal from the termination condition value.

(8)

The measurement method for an electrical characteristic according to (7), wherein, when the prescribed probability of reversal is to be obtained from the termination condition value, using a table in which the termination condition value and the prescribed probability of reversal are associated, the prescribed probability of reversal is obtained from the termination condition value.

(9)

The measurement method for an electrical characteristic according to any one of (1) to (8), further including:

determining whether or not an elapsed time after the voltage is applied has reached a prescribed time.

(10)

The measurement method for an electrical characteristic according to any one of (1) to (9), further including:

obtaining an average stable current value by averaging a plurality of current values determined to be stable.

(11)

The measurement method for an electrical characteristic according to any one of (1) to (10), further including:

obtaining the electrical characteristic of an element based on a current value determined to be stable.

(12)

The measurement method for an electrical characteristic according to (11), wherein the electrical characteristic is a current-voltage characteristic.

(13)

The measurement method for an electrical characteristic according to (11) or (12), wherein the electrical characteristic is at least one kind selected from a group that includes an open voltage Voc, a short-circuit current Isc, a maximum output value Pmax, a maximum output voltage Vmax, a maximum output current value Imax, a series resistance value Rs, a parallel resistance value Rsh, and a fill factor FF.

(14)

The measurement method for an electrical characteristic according to (11), further including:

storing or outputting the obtained electrical characteristic.

(15)

The measurement method for an electrical characteristic according to any one of (1) to (14), further including:

storing time taken to determine the stability of the current value after the voltage is applied.

(16)

The measurement method for an electrical characteristic according to any one of (1) to (15), wherein the element is a dye-sensitized photoelectric conversion element.

(17)

A measurement program for an electrical characteristic causing a computer device to execute a measurement method including:

applying a voltage to an element; and

determining stability of a current value at the applied voltage.

(18)

A measurement device for an electrical characteristic including:

a control unit configured to control a power source unit such that a voltage is applied to an element and stability of a current value at the applied voltage is determined. (19) A recording medium on which a measurement program for an electrical characteristic causing a computer device to execute a measurement method is recorded, the method including applying a voltage to an element and determining stability of a current value at the applied voltage.

### REFERENCE SIGNS LIST

1 sample
11 control device 11
12 four-quadrant power source
13 thermostatic bath
14 light irradiator

1. A measurement method for an electrical characteristic, the measurement method comprising:
applying a voltage to an element; and
determining stability of a current value at the applied voltage.

2. The measurement method for an electrical characteristic according to claim 1,
wherein, during application of the voltage, the voltage is applied to the element while stopping the voltage point by point, and
wherein, during determination of stability of the current value, the stability of the current value is determined at each voltage stopped point by point.

3. The measurement method for an electrical characteristic according to claim 1, wherein determining the stabilized current value includes obtaining the number of reversals of the sign of a current change amount and then determining whether or not the current has been stabilized based on the number of reversals.

4. The measurement method for an electrical characteristic according to claim 1, wherein determining the stabilized current value includes obtaining a probability of reversal of the sign of the current change amount and then determining whether or not the current has been stabilized based on the probability of reversal.

5. The measurement method for an electrical characteristic according to claim 4, wherein determining the stabilized current value includes obtaining the probability of reversal of the sign of the current change amount and then determining whether or not the probability of reversal exceeds a prescribed probability of reversal.

6. The measurement method for an electrical characteristic according to claim 4, wherein determining the stabilized current value includes obtaining an approximation function of the probability of reversal of the sign, and then determining whether or not the value of the approximation function exceeds a prescribed probability of reversal.

7. The measurement method for an electrical characteristic according to claim 6, further comprising:
obtaining a termination condition value from elapsed times T1 and T2 after the voltage is applied and a measurement interval Δt of the current value; and
obtaining the prescribed probability of reversal from the termination condition value.

8. The measurement method for an electrical characteristic according to claim 7, wherein, when the prescribed probability of reversal is to be obtained from the termination condition value, using a table in which the termination condition value and the prescribed probability of reversal are associated, the prescribed probability of reversal is obtained from the termination condition value.

9. The measurement method for an electrical characteristic according to claim 1, further comprising:
determining whether or not an elapsed time after the voltage is applied has reached a prescribed time.

10. The measurement method for an electrical characteristic according to claim 1, further comprising:
obtaining an average stable current value by averaging a plurality of current values determined to be stable.

11. The measurement method for an electrical characteristic according to claim 1, further comprising:
obtaining the electrical characteristic of an element based on a current value determined to be stable.

12. The measurement method for an electrical characteristic according to claim 11, wherein the electrical characteristic is a current-voltage characteristic.

13. The measurement method for an electrical characteristic according to claim 11, wherein the electrical characteristic is at least one kind selected from a group that includes an open voltage Voc, a short-circuit current Isc, a maximum output value Pmax, a maximum output voltage Vmax, a maximum output current value Imax, a series resistance value Rs, a parallel resistance value Rsh, and a fill factor FF.

14. The measurement method for an electrical characteristic according to claim 11, further comprising:
storing or outputting the obtained electrical characteristic.

15. The measurement method for an electrical characteristic according to claim 1, further comprising:
storing time taken to determine the stability of the current value after the voltage is applied.

16. The measurement method for an electrical characteristic according to claim 1, wherein the element is a dye-sensitized photoelectric conversion element.

17. A measurement program for an electrical characteristic causing a computer device to execute a measurement method comprising:
applying a voltage to an element; and
determining stability of a current value at the applied voltage.

18. A measurement device for an electrical characteristic comprising:
a control unit configured to control a power source unit such that a voltage is applied to an element and stability of a current value at the applied voltage is determined.
